(19) United States
(12) Patent Application Publication
(10) Pub. No.: US 2025/0142822 A1
(43) Pub. Date: May 1, 2025

(54) SEMICONDUCTOR DEVICE AND METHOD FOR MANUFACTURING THE SAME, AND ELECTRONIC SYSTEM INCLUDING SEMICONDUCTOR DEVICE

(71) Applicant: SAMSUNG ELECTRONICS CO., LTD., SUWON-SI (KR)

(72) Inventor: Daehwan CHOI, Suwon-si (KR)

(21) Appl. No.: 18/653,101

(22) Filed: May 2, 2024

(30) Foreign Application Priority Data
Nov. 1, 2023 (KR) 10-2023-0149046

(51) Int. Cl. H10B 43/27; H01L 25/065; H10B 43/35; H10B 43/40; H10B 80/00

(52) U.S. Cl. CPC H10B 43/27; H01L 25/0652; H10B 43/35; H10B 43/40; H10B 80/00; H01L 2225/06506

(57) ABSTRACT

A semiconductor device includes: a substrate including a cell array region and a contact region; a gate stacking structure including a plurality of interlayer insulation layers and a plurality of gate electrodes alternately stacked on the substrate; a channel structure penetrating the gate stacking structure in the cell array region; an upper insulation layer covering the gate stacking structure and the channel structure; and a plurality of gate contact parts penetrating the upper insulation layer and connected to the plurality of gate electrodes in the contact region, wherein at least a part of some of the plurality of gate contact parts penetrates at least one passing gate electrode among the plurality of gate electrodes and integrates with a connection gate electrode of the plurality of gate electrodes, and at least a part of an upper surface of the upper insulation layer has a concave shape protruding toward the substrate.

### CROSS-REFERENCE TO RELATED APPLICATION

This application claims priority under 35 U.S.C. § 119 to Korean Patent Application No. 10-2023-0149046, filed in the Korean Intellectual Property Office on Nov. 1, 2023, the disclosure of which is incorporated by reference herein in its entirety.

### TECHNICAL FIELD

The present inventive concept relates to a semiconductor device, a manufacturing method of the same, and an electronic system including the semiconductor device.

### DISCUSSION OF THE RELATED ART

A semiconductor is a material with properties existing between a conductor and an insulator and refers to a material that conducts electricity under predetermined conditions. A variety of semiconductor devices may be manufactured by using a semiconductor material, and for example, a memory device or the like may be manufactured. The memory device may be a volatile memory device or a non-volatile memory device. The non-volatile memory device might not lose data in the absence of power and may be used for various electronic devices such as a portable phone, a digital camera, and a personal computer (PC).

It is desirable to increase the integration density of a non-volatile memory device according to address increasing demand for increased storage capacity. The integration density of a memory device that is two-dimensionally disposed in a plane may be limited. Accordingly, a vertical non-volatile memory device that is three-dimensionally disposed has been under development.

### SUMMARY OF THE INVENTION

According to an embodiment of the present inventive concept, a semiconductor device includes: a substrate including a cell array region and a contact region; a gate stacking structure including a plurality of interlayer insulation layers and a plurality of gate electrodes which are alternately stacked on the substrate; a channel structure penetrating the gate stacking structure in the cell array region; an upper insulation layer covering the gate stacking structure and the channel structure; and a plurality of gate contact parts penetrating the upper insulation layer and connected to the plurality of gate electrodes in the contact region, wherein at least a part of some of the plurality of gate contact parts penetrates at least one passing gate electrode among the plurality of gate electrodes and integrates with a connection gate electrode, of the plurality of gate electrodes, positioned under the at least on passing gate electrode, and at least a part of an upper surface of the upper insulation layer has a concave shape protruding toward the substrate.

According to an embodiment of the present inventive concept, an electronic system includes: a main substrate; a semiconductor device on the main substrate; and a controller electrically connected to the semiconductor device on the main substrate, wherein the semiconductor device includes: a circuit region including a peripheral circuit structure; a cell region positioned on the circuit region; a substrate including a cell array region and a contact region adjacent to the cell region; a gate stacking structure including a plurality of interlayer insulation layers and a plurality of gate electrodes which are alternately stacked on the substrate; a channel structure penetrating the gate stacking structure and extending in one direction in the cell array region; an upper insulation layer covering the gate stacking structure and the channel structure; and a plurality of gate contact parts penetrating the upper insulation layer and connected to the plurality of gate electrodes in the contact region, wherein, at least a part of some of the plurality of gate contact parts penetrates at least one passing gate electrode among the plurality of gate electrodes and is connected to a connection gate electrode, of the plurality of gate electrodes, positioned under the at least one passing gate electrode, and at least a part of an upper surface of the upper insulation layer has a concave shape protruding toward the substrate.

According to an embodiment of the present inventive concept, a method for manufacturing a semiconductor device includes: forming a stacking structure by alternately stacking a sacrificial insulation layer and an interlayer insulation layer on a substrate, which includes a first region and a second region; forming an upper insulation layer on the stacking structure; forming a channel structure penetrating the stacking structure in the first region; forming a plurality of contact holes penetrating at least a part of the stacking structure by using a mask pattern and having different depths from each other in the second region; forming a gate spacer on sidewalls of the plurality of contact holes; forming a sacrificial contact part in the plurality of contact holes; removing the mask pattern by using a chemical mechanical polishing process; and removing the sacrificial insulation layer and the sacrificial contact part; and forming a plurality of gate electrodes and a plurality of gate contact parts in spaces that are formed by the removal of the sacrificial insulation layer and the sacrificial contact part, wherein, when the mask pattern is removed, at least a part of the upper insulation layer is removed with the mask pattern.

### BRIEF DESCRIPTION OF THE DRAWINGS

FIG. 1 is a cross-sectional view illustrating a semiconductor device according to an embodiment of the present inventive concept.

FIGS. 2 and 3 are cross-sectional views illustrating various channel structures included in a semiconductor device of FIG. 1.

FIG. 4 is an enlarged cross-sectional view for S1 region of FIG. 1.

FIG. 5 is an enlarged cross-sectional view corresponding to Q1 region and Q2 region of FIG. 1.

FIG. 6 is a cross-sectional view of a contact region of a semiconductor device according to an embodiment of the present inventive concept.

FIG. 7 is an enlarged cross-sectional view for P1 region of FIG. 6.

FIGS. 8, 9, 10, 11, 12, 13, 14, 15, 16, 17, 18 and 19, FIG. 21, and FIGS. 23, 24 and 25 are process cross-sectional views sequentially illustrating a manufacturing method of a semiconductor device according to an embodiment of the present inventive concept.

FIG. 20 and FIG. 22 are cross-sectional views of a semiconductor device according to embodiments of the present inventive concept.

FIG. 26 is a cross-sectional view of a semiconductor device according to embodiments of the present inventive concept.

FIG. 27 is a schematic view of an electronic system including a semiconductor device according to an embodiment of the present inventive concept.

FIG. 28 is a perspective view of an electronic system including a semiconductor device according to an embodiment of the present inventive concept.

FIG. 29 and FIG. 30 are cross-sectional views of a semiconductor package according to an embodiment of the present inventive concept.

### DETAILED DESCRIPTION OF THE EMBODIMENTS

Embodiments of the present inventive concept will be described more fully hereinafter with reference to the accompanying drawings. As those skilled in the art would realize, the described embodiments may be modified in various different ways, all without departing from the spirit and scope of the present inventive concept.

It is to be understood that the same reference numerals are assigned to the same or similar constituent elements throughout the specification and drawings, and thus, their descriptions may be omitted. As used herein, the singular forms “a”, “an”, and “the” are intended to include the plural forms as well, unless the context clearly indicates otherwise.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present therebetween.

In addition, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

In addition, in the specification, the phrase “on a plane” means an object portion is viewed from above, and the phrase “on a cross-section” means a cross-section taken by vertically cutting an object portion is viewed from the side.

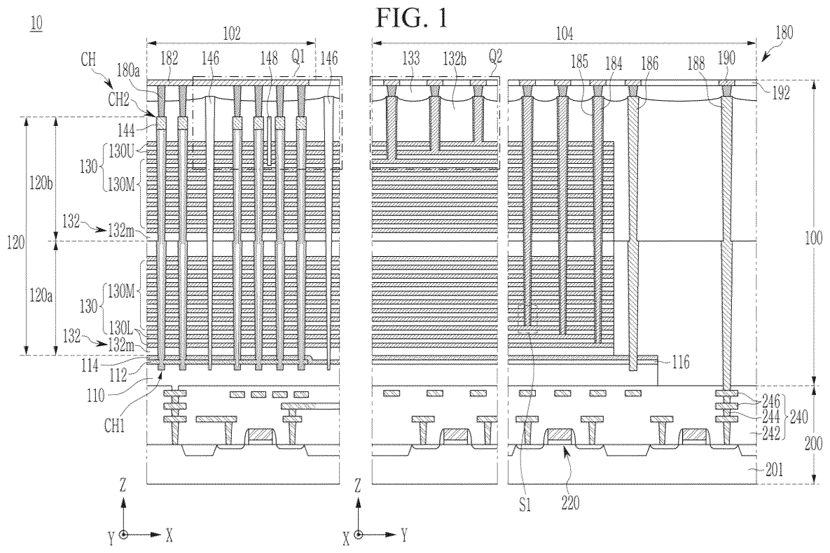

Hereinafter, a semiconductor device according to an embodiment of the present inventive concept is described with reference to FIG. 1 to FIG. 4.

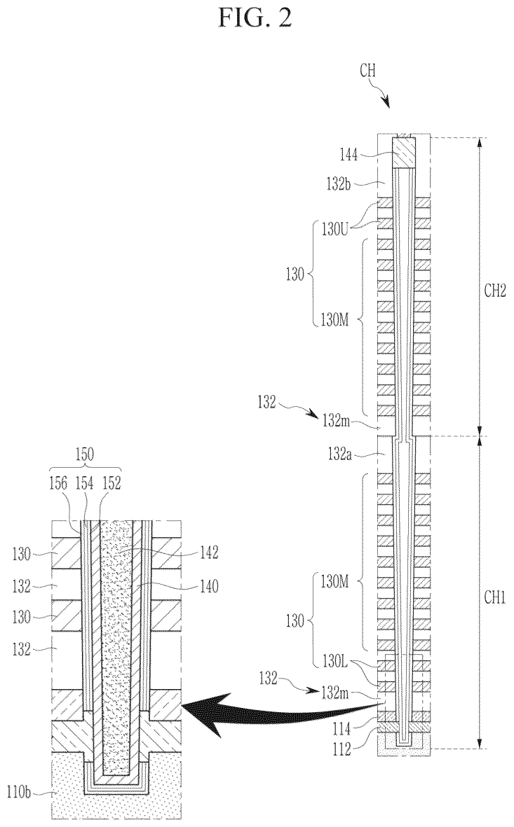

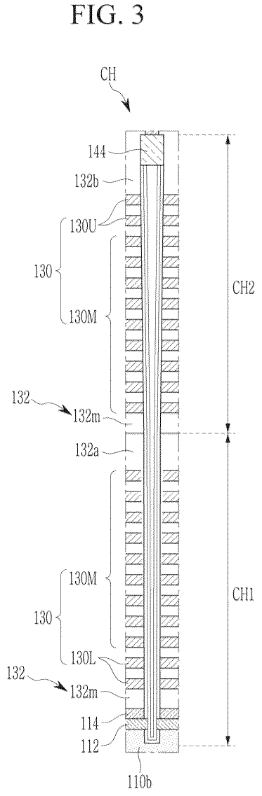

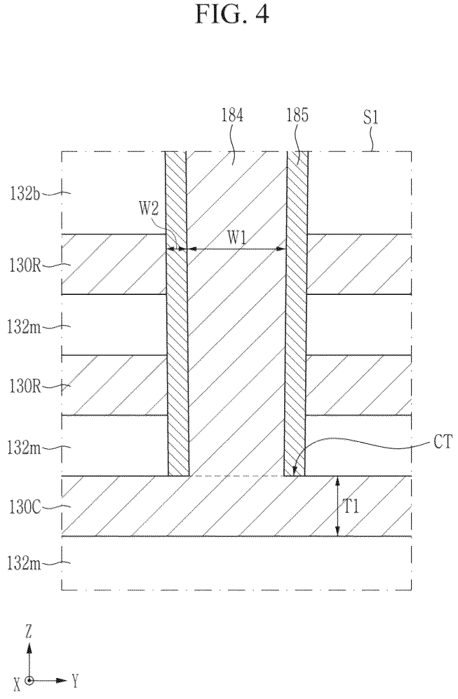

FIG. 1 is a cross-sectional view illustrating a semiconductor device according to an embodiment of the present inventive concept. FIG. 2 and FIG. 3 are cross-sectional views of various channel structures included in a semiconductor device illustrated in FIG. 1. FIG. 4 is an enlarged cross-sectional view for S1 region of FIG. 1.

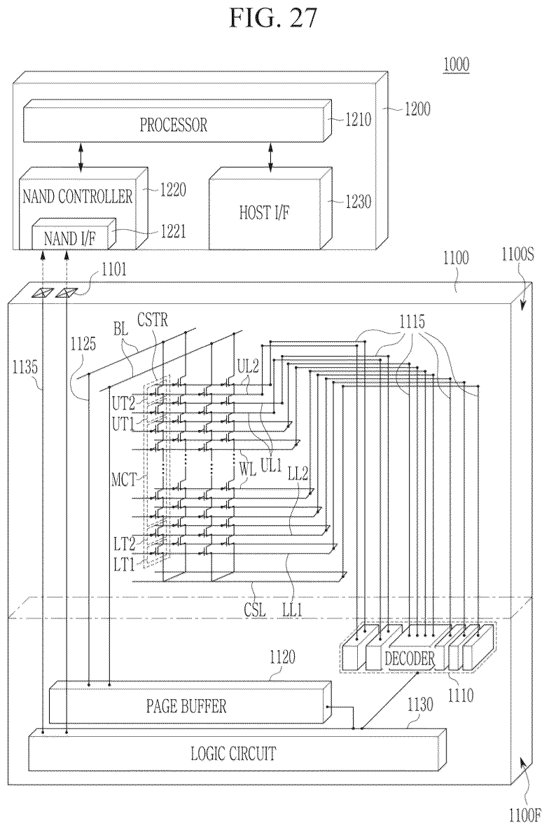

First, referring to FIG. 1, a semiconductor device 10 according to an embodiment of the present inventive concept may include a cell region 100 having a memory cell structure and a circuit region 200 having a peripheral circuit structure for controlling the operation of the memory cell structure. For example, each of the circuit region 200 and the cell region 100 may be portions corresponding to a first structure 1100F and a second structure 1100S of the semiconductor device 1100 included in the electronic system 1000 shown in FIG. 27.

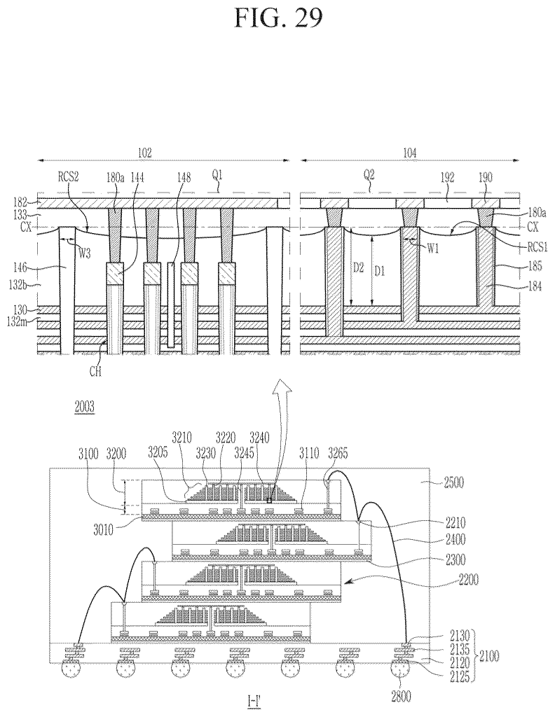

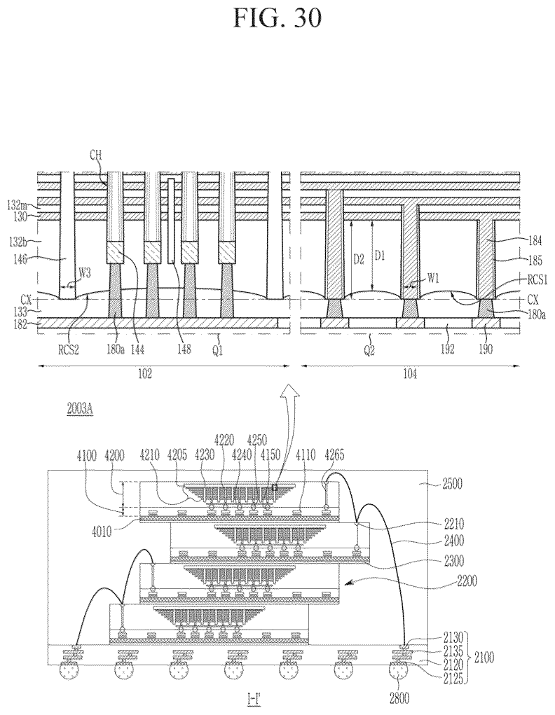

In addition, each of the circuit region 200 and the cell region 100 may be portions corresponding to the first structures 3100, 4100 and the second structures 3200, 4200 of the semiconductor chips 2200 shown in FIG. 29 or 30. Here, the circuit region 200 may include a peripheral circuit structure positioned on a first substrate 201, and the cell region 100 may include a gate stacking structure 120 and a channel structure CH which are positioned at the cell array region 102 on a second substrate 110 as a memory cell structure. A first wire part 240 electrically connected to the peripheral circuit structure may be arranged in the circuit region 200, and a second wire part 180 electrically connected to the memory cell structure may be arranged in the cell region 100.

In an embodiment of the present inventive concept, the cell region 100 may be arranged on the circuit region 200. According to this, as the area corresponding to the circuit region 200 might not be required separately from the cell region 100, thereby the area of the semiconductor device 10 may be reduced. However, the embodiment of the present inventive concept is not limited thereto, and the circuit region 200 may be arranged next to or adjacent to the cell region 100.

The circuit region 200 may include a first substrate 201, a circuit element 220 positioned on the first substrate 201, and a first wire part 240.

The first substrate 201 may be a semiconductor substrate including a semiconductor material. For example, the first substrate 201 may be a semiconductor substrate made of a semiconductor material or may be a semiconductor substrate having a semiconductor layer formed on the base substrate. For example, the first substrate 201 may be made of silicon, epitaxial silicon, germanium, silicon-germanium, silicon-on-insulator (SOI), or germanium-on-insulator (GOI).

The circuit element 220 formed on the first substrate 201 may include various circuit elements for controlling the operation of the memory cell structure provided in the cell region 100. For example, a peripheral circuit structure such as a decoder circuit (1110 of FIG. 27), a page buffer (1120 of FIG. 27), and a logic circuit (1130 of FIG. 27) may include the circuit element 220.

The circuit element 220 may include, for example, a transistor, but the present inventive concept is not limited thereto. For example, circuit element 220 may include not only an active element such as a transistor but also a passive element such as a capacitor, a resistor, and an inductor, etc.

The first wire part 240 disposed on the first substrate 201 may be electrically connected to the circuit element 220. In an embodiment of the present inventive concept, the first wire part 240 may include a plurality of wiring layers 246 spaced apart from each other with the first wiring insulation layer 242 interposed therebetween, and the plurality of wiring layers 246 may be connected to each other by contact vias 244. The wiring layer 246 and/or the contact via 244 may include various conductive materials, and the first wiring insulation layer 242 may include various insulation materials.

The cell region 100 may include a cell array region 102 and a contact region 104. A gate stacking structure 120 and a channel structure CH may be positioned in the second substrate 110 in the cell array region 102. In the contact region 104, there may be a gate stacking structure 120, which is disposed on the second substrate 110, a plurality of gate contact parts 184, which connect the gate stacking structure 120 of the cell array region 102 to the circuit region 200 or an external circuit, and/or a structure, which connects the channel structure CH to the circuit region 200 or the external circuit.

The cell region 100 of the semiconductor device 10 according to an embodiment of the present inventive concept may include a second substrate 110, a gate stacking structure 120 positioned on the second substrate 110, a channel structure CH penetrating the gate stacking structure 120, a separation structure 146 penetrating the gate stacking structure 120, and an upper insulation layer 132b covering the gate stacking structure 120.

The second substrate 110 may include a semiconductor material. For example, the second substrate 110 may include polysilicon doped with impurities. The second substrate 110 may perform a function as a common source line. The second substrate 110 may function as a source region for supplying a current to memory cells that are positioned on the second substrate 110. The second substrate 110 may be formed in a plate form. For example, the second substrate 110 may be prepared with a plate common source line. For example, the second substrate 110 may have a polygonal shape or a circular shape.

At least a part of the first wire insulation layer 242 may be positioned between the second substrate 110 and the first wire part 240. A part of the first wire insulation layer 242, which is positioned between the second substrate 110 and the first wire part 240, may be formed of a single layer or multiple layers. For example, a layer including silicon nitride and a layer including silicon oxide may be positioned between the second substrate 110 and the first wire part 240. In this case, a layer including silicon oxide may be positioned on the layer including silicon nitride.

Semiconductor device 10 according to an embodiment of the present inventive concept may further include horizontal conductive layers 112 and 114 positioned between the second substrate 110 and the gate stacking structure 120 in the cell array region 102.

The horizontal conductive layers 112 and 114 may serve to electrically connect the channel structure CH and the second substrate 110. For example, the horizontal conductive layers 112 and 114 may include a first horizontal conductive layer 112 and a second horizontal conductive layer 114. The first horizontal conductive layer 112 may be positioned on the first surface of the second substrate 110, and the second horizontal conductive layer 114 may be positioned on the first horizontal conductive layer 112. For example, the first horizontal conductive layer 112 may be positioned between the second substrate 110 and the second horizontal conductive layer 114. In a region of the contact region 104, the first horizontal conductive layer 112 might not be provided on the second substrate 110, but the gate stacking structure 120 and a horizontal insulation layer 116 may be provided. For example, the horizontal insulation layer 116 may be provided between the second substrate 110 and the second horizontal insulation layer 116. In the manufacturing process, a part of the horizontal insulation layer 116 may be replaced with the first horizontal conductive layer 112, and another part of the horizontal insulation layer 116 positioned in the contact region 104 may remain in the contact region 104.

The first horizontal conductive layer 112 may function as a part of a common source line of semiconductor device 10. For example, the first horizontal conductive layer 112 may function as a common source line together with the second substrate 110. As illustrated in an enlarged view of FIG. 2, the channel structure CH may extend to reach the second substrate 110 through the horizontal conductive layers 112 and 114, and therefore, the gate dielectric layer 150 may be removed from an area where the first horizontal conductive layer 112 is positioned so that the first horizontal conductive layer 112 may be directly connected to the channel layer 140. For example, the first horizontal conductive layer 112 may be directly connected to a peripheral portion of the channel layer 140. Accordingly, the first horizontal conductive layer 112 may electrically connect the second substrate 110 and the channel layer 140.

The first and second horizontal conductive layers 112 and 114 may include a semiconductor material (e.g., polysilicon). For example, the first horizontal conductive layer 112 may include polysilicon doped with impurities, and the second horizontal conductive layer 114 may include polysilicon doped with impurities or a layer having impurities diffused from the first horizontal conductive layer 112. However, the embodiment is not limited thereto, and the second horizontal conductive layer 114 may include an insulation material. In addition, the second horizontal conductive layer 114 might not be separately provided.

A gate stacking structure 120, in which a cell insulation layer 132 and a plurality of gate electrodes 130 are alternately stacked on each other, may be positioned on the second substrate 110 (e.g., on the first and second horizontal conductive layers 112 and 114 formed on the second substrate 110).

In an embodiment of the present inventive concept, the gate stacking structure 120 may include a plurality of gate stacking structures 120a and 120b sequentially stacked on the second substrate 110. In an embodiment of the present inventive concept, the gate stacking structure 120 may include a plurality of gate stacking structures 120a and 120b sequentially stacked on the second substrate 110. For example, the structure may be simplified while increasing a data storage capacity of the gate stacking structure 120 including the first and second gate stacking structures 120a and 120b. However, the present embodiment is not limited to this, and the gate stacking structure 120 may have one gate stacking structure, or may have three or more gate stacking structures.

In an embodiment of the present inventive concept, the gate stacking structure 120 may extend to the contact region 104. For example, the gate stacking structure 120 may be positioned on the cell array region 102 and the contact region 104. In this case, the length of the layers of the gate stacking structure 120 may be substantially equal to one another. For example, respective lengths of the plurality of gate electrodes 130 and the interlayer insulation layer 132m extending in the second direction (Y direction) may be substantially equal to one another. For example, respective edges of the plurality of gate electrodes 130 and the interlayer insulation layer 132m may be aligned with each other at the same boundary. Accordingly, the side surface of the gate stacking structure 120 may be aligned with the second substrate 110 in the third direction (Z direction).

In the gate stacking structure 120, a plurality of gate electrodes 130 may include a lower gate electrode 130L, a memory cell gate electrode 130M, and an upper gate electrode 130U sequentially positioned from the second substrate 110. The lower gate electrode 130L may be used as a gate electrode of a ground selection transistor. A memory cell gate electrode 130M may constitute a memory cell, and an upper gate electrode 130U may be used as a gate electrode of a string selection transistor. The number of memory cell gate electrodes 130M may be determined according to the data storage capacity of the semiconductor device 10. According to an embodiment of the present inventive concept, one or two or more lower gate electrodes 130L and upper gate electrodes 130U may be provided, respectively, and may have the same structure or different structure as the memory cell gate electrode 130M. Additionally, a part of the plurality of gate electrodes 130, for example, a lower gate electrode 130L and a memory cell gate electrode 130M that is adjacent to the upper gate electrode 130U may be dummy gate electrodes.

The cell insulation layer 132 may include an interlayer insulation layer 132m which is positioned below the plurality of gate electrodes 130 or between a gate electrode 130 of the first gate stacking structure 120a and a gate electrode of the second gate stacking structures 120a and 120b. The cell insulation layer 132 may further include an intermediate insulation layer 132a which is positioned between a gate electrode 130 of the first gate stacking structure 120a and a gate electrode of the second gate stacking structures 120a and 120b. For example, the intermediate insulation layer 132a may be positioned below the interlayer insulation layer 132m that is positioned between a gate electrode 130 of the first gate stacking structure 120a and a gate electrode of the second gate stacking structures 120a and 120b. In this case, the intermediate insulation layer 132a may be an insulation layer positioned between the first gate stacking structure 120a and the second gate stacking structure 120b.

In an embodiment of the present inventive concept, the upper insulation layer 132b may be positioned on the second gate stacking structure 120b. The upper insulation layer 132b may cover the gate stacking structure 120. The upper insulation layer 132b may partially or entirely constitute a cell region insulation layer positioned on the entire upper portion of cell region 100.

In an embodiment of the present inventive concept, at least a part of the upper surface of the upper insulation layer 132b may include a concave shape that protrudes toward the upper surface of the second substrate 110.

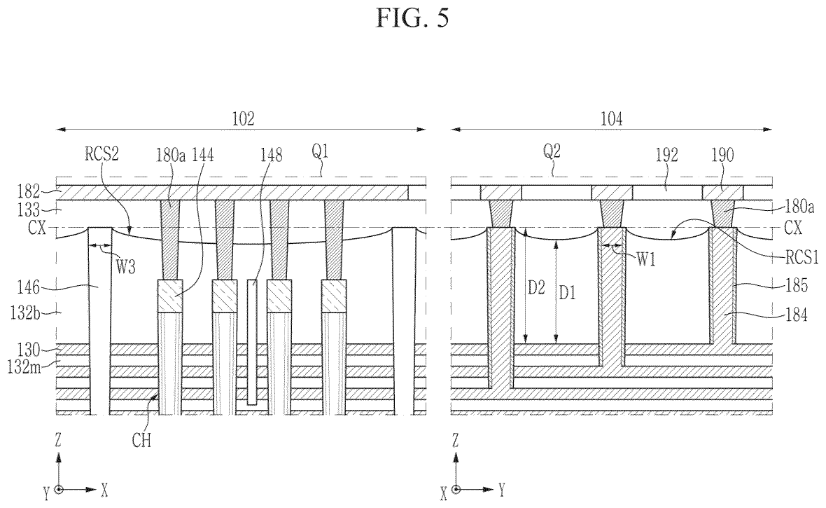

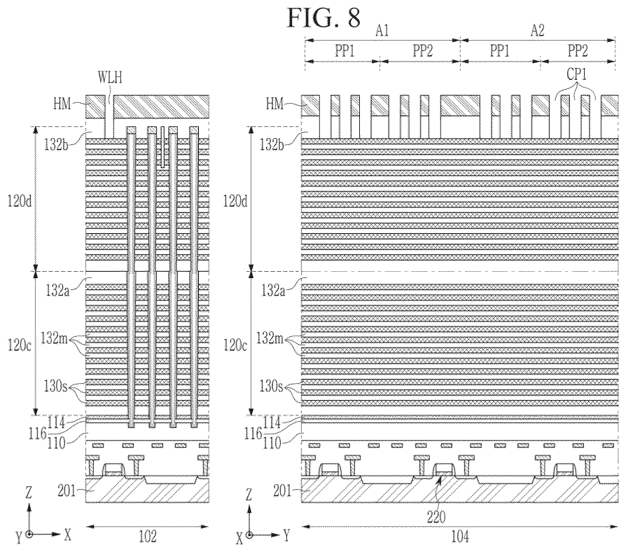

For example, at least a part of the upper insulation layer 132b may include a first recess part RCS1, which is positioned in the contact region 104 and has a concave shape protruding toward the upper surface of the second substrate 110, and a second recess part RCS2, which is positioned in the cell array region 102 and has a concave shape protruding toward the upper surface of the second substrate 110. The shape of the recess parts RCS1 and RCS2 may result from a process characteristic in which at least a part of the upper insulation layer 132b is removed in the process of removing a hard mask pattern (HM of FIG. 8) that is positioned on the upper insulation layer 132b by using a chemical mechanical polishing process. A detailed description of the recess part RCS1 and RCS2 will be described later with reference to FIG. 5.

In an embodiment of the present inventive concept, the thickness of the upper insulation layer 132b may be greater than the thickness of the interlayer insulation layer 132m. In addition, the thickness of the upper insulation layer 132b may be greater than the thickness of the intermediate insulation layer 132a. However, the shape and structure of the upper insulation layer 132b may be variously changed according to an embodiment of the present inventive concept.

The semiconductor device 10 according to an embodiment of the present inventive concept may further include a contact insulation layer 133 positioned on the upper insulation layer 132b.

The contact insulation layer 133 may be positioned on the upper insulation layer 132b.

The contact insulation layer 133 may cover the upper insulation layer 132b.

For example, the contact insulation layer 133 may cover the first recess part (RCS1 in FIG. 5) and the second recess part (RCS2 in FIG. 5) of the upper insulation layer 132b. The bottom surface of the contact insulation layer 133 may have a shape complementary to the upper surface of the upper insulation layer 132b. The contact insulation layer 133 may include various insulation materials. For example, the contact insulation layer 133 may include silicon oxide, silicon nitride, silicon oxynitride, low dielectric constant material having a dielectric constant that is lower than the dielectric constant of silicon oxide, or a combination thereof.

For simplicity of illustration, the drawing illustrates that the cell insulation layer 132 has a boundary between the first gate stacking structure 120a and the second gate stacking structure 120b in the contact region 104. However, the embodiment is not limited to thereto. In the contact region 104, a plurality of insulation layers may have various stacking structures, and embodiments are not limited thereto.

A plurality of gate electrodes 130 may include various conductive materials. For example, a plurality of gate electrodes 130 may include a metal material such as tungsten (W), copper (Cu), aluminum (Al), etc. In another example, a plurality of gate electrodes 130 may include polysilicon, metal nitride (e.g., titanium nitride TiN), tantalum nitride (TaN), or a combination thereof. An insulation layer made of an insulation material may be positioned outside the plurality of gate electrodes 130, or a part of the gate dielectric layer 150 may be positioned. The cell insulation layer 132 may include various insulation materials. For example, the cell insulation layer 132 may include silicon oxide, silicon nitride, silicon oxynitride, a low dielectric constant material with a dielectric constant lower than the dielectric constant of silicon oxide, or a combination thereof.

In one embodiment of the present inventive concept, a channel structure CH may extend in the direction (e.g., a third direction (Z direction)) through the gate stacking structure 120 and may cross the second substrate 110.

The channel structure CH of semiconductor device 10 according to an embodiment of the present inventive concept may include a channel layer 140 and a gate dielectric layer 150 positioned between the plurality of gate electrodes 130 and the channel layer 140. The channel structure CH may further include a core insulation layer 142, which is positioned inside the channel layer 140, and a channel pad 144, which is positioned above the channel layer 140 and/or the gate dielectric layer 150.

Each channel structures CH is composed of one memory cell string, and, on a plane, a plurality of channel structures CH may be arranged with spaced apart from each other while forming rows and columns. For example, on a plane, a plurality of channel structures CH may be arranged in various forms such as a lattice shape and a zigzag shape. The channel structure CH may have a cylindrical shape. For example, when viewed in cross section, the channel structure CH may have an inclined side surface so that a width thereof becomes narrower depending on the aspect ratio as it approaches the second substrate 110. However, the embodiment is not limited thereto, and the arrangement, structure, and shape of the channel structure CH may be variously changed. Referring further to FIGS. 2 and 3, a core insulation layer 142 may be provided in a central region of the channel structure CH, and a channel layer 140 may be disposed while surrounding a sidewall of the core insulation layer 142. For example, the core insulation layer 142 may have a column shape (e.g., a cylindrical shape or a polygonal column shape), and the channel layer 140 may have a planar shape such as an annular shape. However, the embodiment is not limited to thereto, and the core insulation layer 142 might not be provided and the channel layer 140 may have a column shape (for example, a cylindrical shape or a polygonal column shape).

The channel layer 140 may include a semiconductor material, for example, polysilicon. The core insulation layer 142 may include various insulation materials. For example, the core insulation layer 142 may include silicon oxide, silicon nitride, silicon oxynitride, or a combination thereof. However, the material of the channel layer 140 and the material of the core insulation layer 142 are not limited thereto.

The gate dielectric layer 150 positioned between a plurality of gate electrodes 130 and channel layer 140 may include a tunneling layer 152, a charge storage layer 154, and a blocking layer 156 sequentially stacked on the channel layer 140.

The tunneling layer 152 is a layer through which charges are tunneled according to voltages applied to a plurality of gate electrodes 130 and may include an insulation material capable of tunneling charges. The tunneling layer 152 may include a material such as silicon oxide or silicon oxynitride. For example, the tunneling layer 152 may be formed by stacking a silicon oxide including layer and a silicon nitride including layer.

The charge storage layer 154 disposed between a tunneling layer 152 and a blocking layer 156 may be used as a data storage region. For example, the charge storage layer 154 may include a silicon nitride capable of trapping charges. When the charge storage layer 154 includes silicon nitride, it may be excellent in retention and be advantageous for integration compared to the composition of polysilicon. However, the material of the charge storage layer 154 is not limited thereto.

The blocking layer 156 may be disposed between the charge storage layer 154 and a plurality of gate electrodes 130. The blocking layer 156 may include an insulation material capable of preventing an unwanted inflow of charges into the plurality of gate electrodes 130. For example, the blocking layer 156 may include silicon oxide, silicon nitride, silicon oxynitride, high dielectric constant material, or a combination thereof.

Here, the high dielectric constant material is a dielectric material having a dielectric constant that is higher than the dielectric constant of silicon oxide. For example, the high dielectric constant material may include aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide (HfO2), hafnium silicon oxide (HfSixOy), lanthanum oxide (La2O3), lanthanum aluminum oxide (LaAlxOy), lanthanum hafnium oxide (LaHfxOy), hafnium aluminum oxide (HfAlxOy), praseodymium oxide (Pr2O3), or a combination thereof.

A channel pad 144 may be positioned on the channel layer 140 and/or the gate dielectric layer 150. The channel pad 144 may be disposed to cover an upper surface of the core insulation layer 142 and to be electrically connected to the channel layer 140. In FIG. 1 to FIG. 3, the channel pad 144 is shown to cover the upper surface of the gate dielectric layer 150, but the present inventive concept is not limited thereto. For example, the channel pad 144 might not cover the upper surface of the gate dielectric layer 150. In this case, the side surface of channel pad 144 may be surrounded by the gate dielectric layer 150. The side surface of the channel pad 144 may be covered by the tunneling layer 152. For example, the side surface of the channel pad 144 may be in contact with the tunneling layer 152. The channel pad 144 may include a conductive material, for example, polysilicon doped with impurities. However, the material of the channel pad 144 is not limited thereto and may be variously changed.

As described above, when the gate stacking structure 120 includes a plurality of gate stacking structures 120a and 120b stacked on each other, the channel structure CH may include a plurality of channel structures CH1 and CH2 penetrating the plurality of gate stacking structures 120a and 120b, respectively. For example, when a plurality of gate stacking structures 120 includes the first gate stacking structure 120a and the second gate stacking structure 120b, a plurality of channel structures CH may include a first channel structure CH1 and a second channel structure CH2. The first channel structure CH1 extends through the first gate stacking structure 120a, and the second channel structure CH2 extends through the second gate stacking structure 120b.

The first channel structure CH1 and the second channel structure CH2 may have an interconnected shape. Each of the first channel structure CH1 and the second channel structure CH2, when viewed in cross section, may have an inclined side surface so that a width thereof becomes narrower toward the second substrate 110 depending on the aspect ratio. As illustrated in FIG. 2, a bent part may be provided due to a difference in width at a portion where the first channel structure CH1 and the second channel structure CH2 are connected to each other. As another example illustrated in FIG. 3, the first channel structure CH1 and the second channel structure CH2 may have an inclined side surface in which they are continuously connected without a bent part. However, the shapes of the first channel structure CH1 and the second channel structure CH2 are not limited thereto and may be variously changed.

In FIG. 1, the gate dielectric layer 150, channel layer 140, and core insulation layer 142 of the first channel structure CH1 and the second channel structure CH2 have an integral structure formed throughout the first channel structure CH1 and the second channel structure CH2 that are connected to each other. After the first penetrating part for the first channel structure CH1 and the second penetrating part for the second channel structure CH2 are formed, the gate dielectric layer 150, the channel layer 140, and the core insulation layer 142 may be formed over the entirety of the first and second penetrating parts to form the above-described structure. However, the embodiment is not limited to thereto. As another example, the gate dielectric layer 150, the channel layer 140, and the core insulation layer 142 of the first channel structure CH1 may be formed separately from and electrically connected to the gate dielectric layer 150, the channel layer 140, and the core insulation layer 142 of the second channel structure CH2. For example, a gate dielectric layer 150, a channel layer 140, and a core insulation layer 142 may be formed in the first penetrating part after the first penetrating part for the first channel structure CH1 is formed, and a gate dielectric layer 150, a channel layer 140, and a core insulation layer 142 may be formed in the second penetrating part after the second penetrating part for the second channel structure CH2 is formed. Besides the above, it is possible to provide various changes.

In an embodiment of the present inventive concept, the channel pad 144 may be provided on the channel structure CH (e.g., the second channel structure CH2) that is provided in the gate stacking structure 120 (e.g., the second gate stacking structure 120b) positioned on the upper part of the plurality of gate stacking structures 120. Unlike this, a channel pad 144 may be provided on the first channel structure CH1 and the second channel structure CH2, respectively. In this case, the channel pad 144 of the first channel structure CH1 may be connected to the channel layer 140 of the second channel structure CH2.

In an embodiment of the present inventive concept, the separation structure 146 may extend in the third direction (Z direction) and penetrate the gate stacking structure 120. For example, the separation structure 146 may extend to the second substrate 110 through a plurality of gate electrodes 130 and cell insulation layers 132. For example, the separation structure 146 may penetrate a plurality of gate electrodes 130, a cell insulation layer 132, and horizontal conductive layers 112 and 114, and may penetrate at least a part of the second substrate 110.

The separation structure 146 may extend to a second direction (Y direction) on a plane and there may be a plurality of separation structures 146 that are spaced apart from each other at a predetermined distance in a first direction (X direction) intersecting the second direction (Y direction). Accordingly, on a plane, each of the plurality of gate stacking structures 120 may extend to the second direction (Y direction) and may be spaced apart from each other with a predetermined distance in the first direction (X direction). The gate stacking structure 120 partitioned by the separation structure 146 may be composed of one memory cell block. However, the embodiment is not limited to this, and the range of the memory cell block is not limited thereto.

In an embodiment of the present inventive concept, an upper surface of the separation structure 146 may be positioned at a higher level than an upper surface of the channel structure CH. For example, the upper surface of the separation structure 146 may be positioned farther from the upper surface of the second substrate 110 than the upper surface of the channel structure CH.

Due to a high aspect ratio, the separation structure 146 may have an inclined side surface whose width decreases as the second substrate 110 is approached when viewed in cross section. However, the embodiment is not limited thereto. For example, the side surface of the separation structure 146 may be perpendicular to the second substrate 110, and the width of the separation structure 146 may be constant. In FIG. 1, when viewed in cross section, it is illustrated that the separation structure 146 has a continuous inclined side surface in the first gate stacking structure 120a and the second gate stacking structure 120b and does not include a bent part. However, the embodiment is not limited, and the separation structure 146 may have the bent part at the boundary between the first gate stacking structure 120a and the second gate stacking structure 120b.

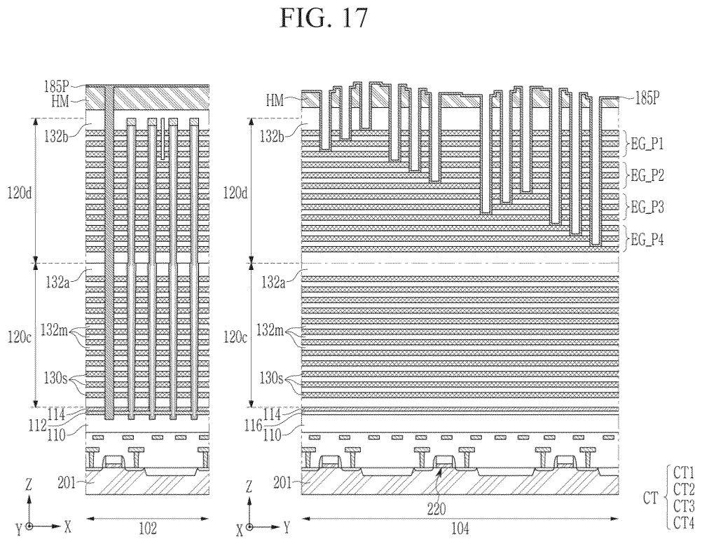

In addition, the separation structure 146 may have at least one bent part in a region penetrating the first gate stacking structure 120a and/or the second gate stacking structure 120b. The separation structure 146 may include various insulation material. The separation structure 146 may include the same material as a gate spacer 185 which will be described later. For example, the separation structure 146 may include at least one of aluminum nitride (AlN), aluminum oxide (AlO), silicon oxide (SiO2), silicon oxynitride (SiON), silicon oxycarbide (SiOC), silicon oxycarbonitride (SiOCN), and/or silicon carbonitride (SiCN). Alternatively, the separation structure 146 may include a high dielectric constant (High-K) material. This, in the process of forming a gate spacer 185, may be result from the process characteristic in which a dummy gate spacer (185P of FIG. 17) is simultaneously formed in the sidewall and the separation hole WLH of the plurality of contact holes CT, so the gate spacer 185 and the separation structure 146 are formed simultaneously.

The semiconductor device 10 according to an embodiment of the present inventive concept may further include an upper separation pattern 148 positioned above the gate stacking structure 120.

The upper separation pattern 148 may extend in the second direction (Y direction) on a plane and may be provided as a plurality that are to be spaced apart from each other at a predetermined distance in the first direction (X direction).

The upper separation pattern 148 may extend to the third direction (Z direction). The upper separation pattern 148 may be positioned to penetrate at least one of the plurality of gate electrodes 130, which includes an upper gate electrode 130U, positioned between separation structures 146. The upper separation pattern 148 may separate, for example, three gate electrodes 130 from each other in the first direction (X direction). However, the number of gate electrodes 130 that are separated by the upper separation pattern 148 is not limited to hereto, and maybe changed in various ways. The upper separation pattern 148 may have a form filled with an insulation material. For example, the upper separation pattern 148 may include an insulation material such as silicon oxide, silicon nitride, or silicon oxynitride. For example, the upper separation pattern 148 may include an insulation material such as silicon oxide, silicon nitride, or silicon oxynitride.

A contact region 104 and a second wire part 180 may be provided to connect the gate stacking structure 120 and the channel structure CH provided in the cell array region 102 to a circuit region 200 or an external circuit.

Here, the second wire part 180 may include all members electrically connecting the plurality of gate electrodes 130, a channel structure CH, the horizontal conductive layers 112 and 114, and/or the second substrate 110 to the circuit region 200 or an external circuit. For example, the second wire part 180 may include a bit line 182, a plurality of gate contact parts 184, a source contact part 186, a through plug 188, a contact via 180a connected thereto, and a connection wire 190 connecting the same. For example, the contact via 180a may be connected to a bit line 182, a plurality of gate contact parts 184, a source contact part 186, and a through plug 188. For example, the connection wire 190 may be connected to a plurality of gate contact parts 184, a source contact part 186, and a through plug 188 through a contact via 180a.

The contact region 104 of the semiconductor device 10 according to an embodiment of the present inventive concept may include a gate stacking structure 120 positioned on the second substrate 110, an upper insulation layer 132b, a plurality of gate contact parts 184 penetrating at least a part of the gate stacking structure 120, and a gate spacer 185 surrounding the plurality of gate contact parts 184.

In the contact region 104, the plurality of gate contact parts 184 may penetrate the gate stacking structure 120 to different depth and be connected to each of the plurality of gate electrodes 130, respectively. A plurality of gate contact parts 184 may extend in the third direction (Z direction).

Referring further to FIG. 4, each of a plurality of gate contact parts 184 may be connected to any one of the gate electrodes 130. For example, any one gate contact part 184 of plurality of gate contact parts 184 may penetrate the upper insulation layer 132b and be electrically connected to the gate electrode 130 positioned at the uppermost part. The remaining a plurality of gate contact parts 184 among the gate contact parts may penetrate the passing gate electrode 130R which is at least a part of the plurality of gate electrodes 130 and may be electrically connected to the connection gate electrode 130C that is positioned under the passing gate electrode 130R. For example, the plurality of gate contact parts 184 may penetrate the gate stacking structure 120 with different depth to fill a plurality of contact holes CT whose bottom surface is defined by an upper surface of the plurality of gate electrodes 130.

Here, based on one plurality of gate contact parts 184, among the plurality of gate electrodes 130, the plurality of gate electrodes 130 penetrated by the plurality of gate contact parts 184 will be called the passing gate electrode 130R, and the plurality of gate electrodes 130 connected to the plurality of gate contact parts 184 will be called the connection gate electrode 130C.

In an embodiment of the present inventive concept, each of a plurality of gate contact parts 184 may be electrically connected to the connection gate electrode 130C, and the passing gate electrode 130R positioned above the connection gate electrode 130C and the remaining plurality of gate electrodes 130 positioned below the connection gate electrode 130C may be electrically insulated from a plurality of gate contact parts 184. For example, the remaining plurality of gate electrodes 130 positioned under the connection gate electrode 130C might not be penetrated by the plurality of gate contact parts 184. Thus, the remaining plurality of gate electrodes 130 positioned under the connection gate electrode 130C may be positioned to be spaced apart from the plurality of gate contact parts 184, and may be insulated from the plurality of gate contact parts 184.

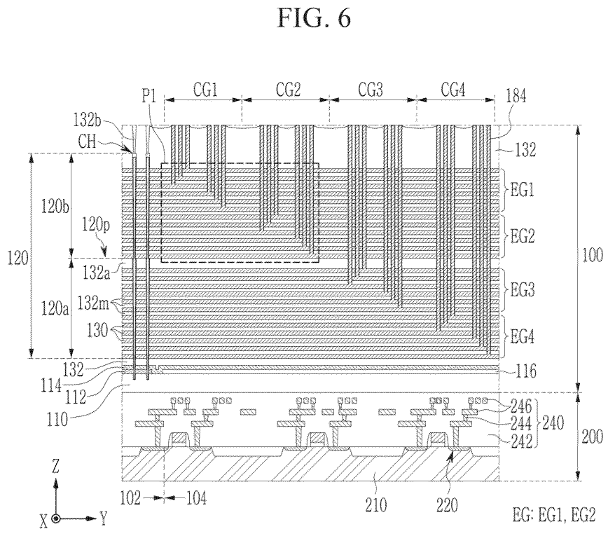

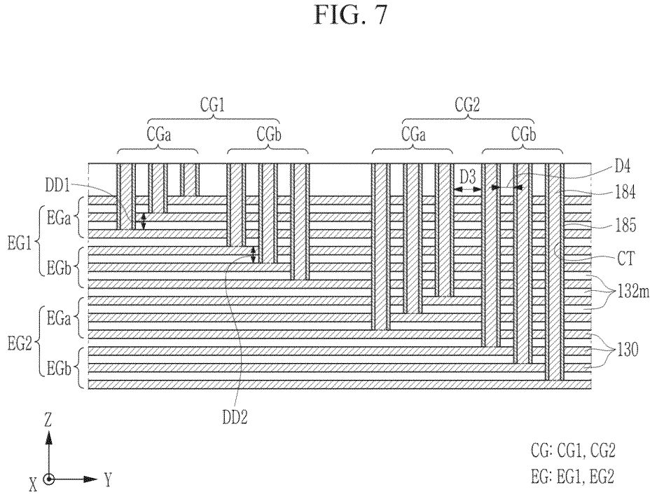

In an embodiment of the present inventive concept, a connection structure between a plurality of gate contact parts 184 and a plurality of gate electrodes 130 may have regularity. For example, a connection structure between an upper group (EGa of FIG. 7) and one side group (CGa of FIG. 7) and a connection structure between a lower group (EGb of FIG. 7) and the other side group (CGb of FIG. 7) may have a structure which is close to being symmetrical. The specific connection structure between plurality of gate contact parts 184 and plurality of gate electrodes 130 will be described later with reference to FIG. 6 and FIG. 7.

In an embodiment of the present inventive concept, a plurality of gate contact parts 184 may be integrally formed with the connection gate electrode 130C. For example, the plurality of gate contact parts 184 may be integrally formed with the connection gate electrode 130C, so that the boundary between the plurality of gate contact parts 184 and the connection gate electrode 130C might not be recognized. Accordingly, the plurality of gate contact parts 184 may be integrated with the gate electrode 130 positioned at different heights, respectively, and the plurality of gate electrodes 130 may be connected to the different gate contact parts 184, respectively. This may be due to the process characteristics of simultaneously removing the sacrificial insulation layer (130s of FIG. 8) and the sacrificial contact part 184s, and simultaneously forming a plurality of gate contact parts 184 and a plurality of gate electrodes 130 in the removed space.

The plurality of gate contact parts 184 may have a cylindrical shape or a rectangular prism shape. As an example, when viewed in cross section, the plurality of gate contact parts 184 may have inclined side surface so that a width thereof becomes narrower as they approach closer to the second substrate 110 depending on the aspect ratio. However, it is not limited to thereto, and, for example, the plurality of gate contact parts 184 may have a constant width depending on the aspect ratio when viewed in cross section.

In this case, a first width W1 in the second direction (Y direction) of the plurality of gate contact parts 184 may be greater than or equal to a first thickness T1 in the third direction (Z direction) of the connection gate electrode 130C. Here, when viewed in cross section, when a plurality of gate contact parts 184 have an inclined side surface so that their widths become narrower toward the second substrate 110 according to the aspect ratio, the first width W1 in the second direction (Y direction) of the plurality of gate contact parts 184 may be a minimum width in the second direction (Y direction) of the plurality of gate contact parts 184. For example, the minimum width of the plurality of gate contact parts 184 in the second direction (Y direction) may be greater than the first thickness T1 in the third direction (Z direction) of the connection gate electrode 130C. In addition, of course, the first width W1 along the second direction (Y direction) of the plurality of gate contact parts 184 may be greater than or equal to a thickness along the third direction (Z direction) of the passing gate electrode 130R.

In addition, in an embodiment of the present inventive concept, since a plurality of gate contact parts 184 and a plurality of gate electrodes 130 are simultaneously formed, when the first width W1 of the plurality of gate contact parts 184 in the second direction (Y direction) is less than the thickness of the plurality of gate electrodes 130 in the third direction (Z direction), a plurality of gate contact parts 184 may be formed first before the plurality of gate electrodes 130 are completely formed. In this case, a void may occur within the plurality of gate electrodes 130, and the resistance of the plurality of gate electrodes 130 may increase or decrease. Therefore, in an embodiment of the present inventive concept, since the first width W1 in the second direction (Y direction) of the plurality of gate contact parts 184 is greater than or equal to the thickness in the third direction (Z direction) of the plurality of gate electrodes 130, a plurality of gate electrodes 130 may be formed before the plurality of gate contact parts 184 are completely formed. Accordingly, it is possible to prevent the formation of voids within the plurality of gate electrodes 130 and increase the reliability of the semiconductor device 10.

In an embodiment of the present inventive concept, the upper surfaces of the plurality of gate contact parts 184 may be positioned at a higher level than the upper surface of the upper insulation layer 132b. For example, the upper surface of plurality of gate contact parts 184 may be positioned at a level that is higher than the upper surface of the upper insulation layer 132b that is positioned between the plurality of gate contact parts 184. For example, the upper surface of plurality of gate contact parts 184 may be positioned farther from the upper surface of the second substrate 110 than the upper surface of the upper insulation layer 132b.

In an embodiment of the present inventive concept, the upper surfaces of the plurality of gate contact parts 184 may be positioned at substantially the same level as that of the upper surfaces of the separation structure 146. For example, the upper surface of multiple gate contact parts 184 and the upper surface of the separation structure 146 may be positioned at substantially the same distance from the upper surface of the second substrate 110. In addition, the first width W1 along the second direction (Y direction) of the plurality of gate contact parts 184 may be greater than the third width (W3 of FIG. 5) along the first direction (X direction) of the separation structure 146. For example, the maximum width along the second direction (Y direction) of the plurality of gate contact parts 184 may be greater than the maximum width along the first direction (X direction) of the separation structure 146.

In an embodiment of the present inventive concept, the plurality of gate contact parts 184 may include various conductive materials. A plurality of gate contact parts 184 may include the same material as a plurality of gate electrodes 130. For example, a plurality of gate contact parts 184 may include metal materials such as tungsten (W), copper (Cu), aluminum (Al), etc. In another example, the plurality of gate contact parts 184 may include polysilicon, metal nitride (e.g., titanium nitride TiN, tantalum nitride TaN, etc.) or a combination thereof. As described above, this may be result from the process characteristics of integrally forming the plurality of gate contact parts 184 and the plurality of gate electrodes 130.

The gate spacer 185 may surround a plurality of gate contact parts 184. For example, the plurality of gate contact parts 184 may be a column shape (e.g., a cylindrical shape or a polygonal column shape), and the gate spacer 185 may be a planar shape such as an annular shape. A gate spacer 185 may overlap the plurality of gate contact parts 184 at an outside portion of the contact hole CT. For example, a gate spacer 185 may contact the plurality of gate contact parts 184 at an outside portion of the contact hole CT. A gate spacer 185 may be positioned on the sidewall of the contact hole CT. However, the embodiment is not limited to thereto, and the gate spacer 185 may partially surround a part of the side surface of the plurality of gate contact parts 184.

The gate spacer 185 may be positioned so that the plurality of gate contact parts 184 are electrically connected to the connection gate electrode 130 and insulated from the passing gate electrode 130. For example, the gate spacer 185 might not be positioned on the bottom surface of the plurality of gate contact parts 184.

In an embodiment of the present inventive concept, the gate spacer 185 may be in contact with the connection gate electrode 130C. For example, the bottom surface of gate spacer 185 may be in contact with the upper surface of the connection gate electrode 130C. Accordingly, the bottom surface of the gate spacer 185 may be aligned at the same boundary as the bottom surface of the plurality of gate contact parts 184. Accordingly, the gate spacer 185 may surround the entire side surface of the plurality of gate contact parts 184 and may insulate between the plurality of gate contact parts 184 and the plurality of adjacent gate electrodes 130. In an embodiment of the present inventive concept, as illustrated in FIG. 4, the second width W2 of the gate spacer 185 in the second direction (Y direction) may be smaller than the first width W1 in the second direction (Y direction) of the plurality of gate contact parts 184. For example, the second width W2 of the gate spacer 185 along the second direction (Y direction) may be about 1/12^{th} to about ⅛^{th} of the first width W1 along the second direction (Y direction) of the plurality of gate contact parts 184. In this range, the gate spacer 185 may stably insulate between the plurality of gate contact parts 184 and the passing gate electrode 130R while providing space for forming a plurality of gate contact parts 184 in a plurality of contact holes CT.

The gate spacer 185 may include various insulation materials. The gate spacer 185 may include the same material as the separation structure 146. For example, the gate spacer 185 may include at least one of aluminum nitride (AlN), aluminum oxide (AIO), silicon oxide (SiO2), silicon oxynitride (SiON), silicon oxycarbide (SiOC), silicon oxycarbonitride (SiOCN), and/or silicon carbonitride (SiCN). In addition, the gate spacer 185 may include a high dielectric constant (high-K) material. This may be result from the process characteristic in the process of forming a gate spacer 185 in which a dummy gate spacer (185P of FIG. 17) is simultaneously formed in the sidewall and the separation hole WLH of the plurality of contact holes CT, so the gate spacer 185 and the separation structure 146 are formed simultaneously. The description will be described later in the manufacturing method of semiconductor device 10 according to an embodiment of the present inventive concept.

In FIG. 1, the gate spacer 185 is shown as a single layer, but the embodiment is not limited thereto, and a layer inevitably formed between the gate spacer 185 and the plurality of gate contact parts 184 may exist, or a separate layer may be provided.

Referring back to FIG. 1, a source contact part 186 may penetrate the cell insulation layer 132 in the contact region 104 to be electrically connected to the horizontal conductive layers 112 and 114 and/or the second substrate 110, and a through plug 188 may be disposed outside the gate stacking structure 120 to be electrically connected to the first wire part 240 of the circuit region 200. However, the present inventive concept is not limited to thereto, and the through plug 188 may penetrate through the gate stacking structure 120 and be electrically connected to a first wire part 240 of the circuit region 200.

The connection wire 190 may be positioned in the cell array region 102 and/or the contact region 104. A bit line 182, a plurality of gate contact part 184, a source contact part 186, and/or a through plug 188 may be electrically connected to the connection wire 190. For example, a plurality of gate contact parts 184, a source contact part 186, and/or a through plug 188 may be connected to a connection wire 190 through contact vias 180a.

The bit line 182 may be positioned on the cell insulation layer 132 of the gate stacking structure 120 in the cell array region 102. The bit line 182 may extend to a first direction (X direction) in which a plurality of gate electrodes 130 extend. The bit line 182 may be electrically connected to a channel structure CH, for example, a channel pad 144, through a contact via 180a, for example, a bit line contact via.

In FIG. 1, the connection wire 190 is provided as a single layer positioned on the same plane as the bit line 182, and the second line insulation layer 192 is positioned in a part other than the second wire part 180. However, this is only a brief illustration for convenience. Therefore, the connection wire 190 may further include a bit line 182, a plurality of gate contact parts 184, a plurality of wiring layers for electrical connection with a source contact part 186 and/or a through plug 188, and a contact via 180a.

Thus, through the second wire part 180 and the first wire part 240, a bit line 182 connected to the channel structure CH, a plurality of gate electrodes 130, horizontal conductive layers 112 and 114 and/or a second substrate 110 may be electrically connected to the circuit element 220 of the circuit region 200.

In FIG. 1, when viewed in cross section, the source contact part 186 and/or the through plug 188 may have an inclined side surface so that a width thereof becomes narrower as it approaches the second substrate 110 according to the aspect ratio, and a bent part is provided at the boundary between the first gate stacking structure 120a and the second gate stacking structure 120b. However, the embodiment is not limited to thereto. For example, the source contact part 186 and/or the through plug 188 might not have a bent part at the boundary between the first gate stacking structure 120a and the second gate stacking structure 120b. Besides the above, it is possible to provide various changes.

Hereinafter, an upper insulation layer of a semiconductor device according to an embodiment of the present inventive concept will be described with reference to FIG. 5.

FIG. 5 is an enlarged cross-sectional view of a Q1 region and a Q2 region of FIG. 1.

Referring to FIG. 1 and FIG. 5, at least a part of the upper insulation layer 132b of the semiconductor device 10 according to an embodiment of the present inventive concept may include recess parts RCS1 and RCS2 that are concave protruding toward the upper surface of the second substrate 110.

The recess parts RCS1 and RCS2 may have a concave shape protruding toward the upper surface of the second substrate 110. The recess parts RCS1 and RCS2 may be due to a process characteristic in which at least a part of the upper insulation layer 132b is removed in a process of removing the hard mask pattern (HM of FIG. 8) positioned on the upper insulation layer 132b using a chemical mechanical polishing process. For example, in the process of removing the hard mask pattern (HM of FIG. 8) using a chemical mechanical polishing process, at least a part of the upper insulation layer 132b, which is positioned between a plurality of gate contact parts 184, and at least a part of the upper insulation layer 132b, which is positioned between the separation structures 146, may be removed together to form the recess parts RCS1 and RCS2. For example, the recess parts RCS1 and RCS2 may be formed by removing at least a part of the upper insulation layer 132b from the reference level CX that is substantially coplanar with the upper surfaces of the plurality of gate contact parts 184. At this time, the gate spacer 185 and the separation structure 146 might not be removed in the process of removing the hard mask pattern (HM in FIG. 8) positioned on the upper insulation layer 132b by using a chemical mechanical polishing process. Therefore, at least a part of the upper insulation layer 132b positioned between the gate spacers 185 and at least a part of the upper insulation layer 132b positioned between the separation structure 146 may be removed.

In an embodiment of the present inventive concept, the upper insulation layer 132b may include a first recess parts RCS1 positioned in the contact region 104 and a second recess part RCS2 positioned in the cell array region 102.

The first recess part RCS1 may be positioned between a plurality of gate contact parts 184. For example, the first recess part RCS1 may be positioned between a plurality of gate contact parts 184 that are positioned spaced apart to the second direction (Y direction). The first recess part RCS1 may have a concave shape protruding toward the upper surface of the second substrate 110. For example, the first recess part RCS1 may have a concave shape protruding toward the upper surface of the second substrate 110 between a plurality of gate contact parts 184. The first recess part RCS1 may include a curved surface having a predetermined curvature in a cross section formed in a second direction (Y direction) and a third direction (Z direction), but is not limited thereto.

The first recess part RCS1 may be caused by a process characteristic in which at least a part of the upper insulation layer 132b is removed together in the process of removing the hard mask pattern (HM of FIG. 8) positioned in the contact region 104 using a chemical mechanical polishing process. For example, in the process of removing the hard mask pattern (HM in FIG. 8) that is positioned in the contact region 104 by using a chemical mechanical polishing process, at least a part of the upper insulation layer 132b that is positioned between the plurality of gate contact parts 184 may be removed with the hard mask pattern to form the first recess part RCS1. For example, the first recess part RCS1 may be formed by removing at least a part of the upper insulation layer 132b from the reference level CX being positioned at substantially the same level as that of the upper surfaces of the plurality of gate contact parts 184. At this time, the gate spacer 185 might not be removed in the process of removing the hard mask pattern (HM of FIG. 8) that is positioned on the upper insulation layer 132b by using a chemical mechanical polishing process. Therefore, a first recess part RCS1 positioned between the gate spacers 185 and having a concave shape protruding toward the upper surface of the second substrate 110 may be formed.

In an embodiment of the present inventive concept, the upper surface of the first recess part RCS1 may be positioned at a lower level than the upper surface of a plurality of gate contact parts 184. For example, the upper surface of the first recess part RCS1 may be positioned closer to the upper surface of the second substrate 110 than the upper surface of a plurality of gate contact parts 184. Accordingly, the length of the upper insulation layer 132b along the third direction (Z direction) may be shorter than the length of the plurality of gate contact parts 184 along the third direction (Z direction).

Here, the length of the upper insulation layer 132b along the third direction (Z direction) may be a distance from the upper surface of the gate electrode 130 positioned at uppermost part, of the plurality of gate electrodes 130, to the upper surface of the upper insulation layer 132b along the third direction (Z direction). In an embodiment of the present inventive concept, since the first recess part RCS1 has a concave shape protruding toward the upper surface of the second substrate 110, the length of the upper insulation layer 132b along the third direction (Z direction) may decrease as the distance from the plurality of gate contact parts 184 increases. For example, the first length D1 in the third direction (Z direction) of the upper insulation layer 132b positioned at the center of the first recess part RCS1 may be shorter than the second length D2 along the third direction (Z direction) of the upper insulation layer 132b positioned at the edge of the first recess part RCS1. In this case, the first length D1 along the third direction (Z direction) of the upper insulation layer 132b which is positioned in the center of the first recess part RCS1 may be the minimum length along the third direction (Z direction) of the upper insulation layer 132b in the contact region 104, but the present inventive concept is not limited thereto.

The second recess part RCS2 may be positioned between the separation structures 146. For example, the second recess part RCS2 may be positioned between the separation structures 146, which are spaced apart from each other, in the first direction (X direction). The second recess part RCS2 may be positioned on the channel structure CH. The second recess part RCS2 may have a concave shape protruding toward the upper surface of the second substrate 110. For example, the second recess part RCS2 may have a concave shape protruding toward the upper surface of the second substrate 110 between the separation structure 146. The second recess part RCS2 may include a curved surface having a predetermined curvature in a cross section formed in a first direction (X direction) and a third direction (Z direction), but the present inventive concept is not limited thereto. For example, the curvature of the second recess part RCS2 may be less than that of the first recess part RCS1.

The second recess part RCS2, in the process of removing the hard mask pattern (HM of FIG. 8) positioned in the cell array region 102 using a chemical mechanical polishing process, may be formed by a process characteristic in which at least a part of the upper insulation layer 132b is removed with the hard mask pattern (HM of FIG. 8). For example, in the process of removing the hard mask pattern (HM of FIG. 8) positioned in the cell array region 102 by using a chemical mechanical polishing process, at least a part of the upper insulation layer 132b that is positioned between the plurality of gate contact parts 184 may be removed with the hard mask pattern (HM of FIG. 8) to form a second recess part RCS2. For example, the second recess part RCS2 may be formed by removing at least a part of the upper insulation layer 132b from the reference level CX that is positioned at substantially the same level as that of the upper surfaces of the plurality of gate contact parts 184. In addition, in the process of removing the hard mask pattern (HM in FIG. 8) positioned on the upper insulation layer 132b by using a chemical mechanical polishing process, the separation structure 146 might not be removed. Therefore, a second recess part RCS2 having a concave shape protruding toward the upper surface of the second substrate 110 may be formed between the separation structures 146.

In an embodiment of the present inventive concept, a degree to which at least a part of the upper insulation layer 132b positioned in the cell array region 102 is removed may be greater than a degree to which at least a part of the upper insulation layer 132b positioned in the contact region 104 is removed. This is, in the process of removing the hard mask pattern HM (HM in FIG. 8) that is positioned on the upper insulation layer 132b by using a chemical mechanical polishing process, because the distance between the separation structures 146 adjacent in the first direction (X direction) is greater than the distance between the gate spacers 185 adjacent in the second direction (Y direction). In other words, a width of the first recess part RCS1 adjacently formed between the gate spacers 185 along the second direction (Y direction) may be narrower than the width of the second recess part RCS2 adjacently provided between the separation structures 146 along the first direction (X direction).

Accordingly, a depth at which the second recess part RCS2 is recessed may be greater than a depth at which the first recess part RCS1 is recessed. That is, the minimum length from the upper surface of the gate electrode 130 positioned at the uppermost part, of the plurality of gate electrodes 130, to the upper surface of the second recess part RCS2 may be shorter than the minimum length from the upper surface of the gate electrode 130 positioned at the uppermost part, of the plurality of gate electrodes 130, to the upper surface of the first recess part RCS1. In addition, in the cross section made up of the first direction (X direction) and the third direction (Z direction), the curvature of the second recess part RCS2 may be less than the curvature of the first recess part RCS1.

In an embodiment of the present inventive concept, an upper surface of the second recess part RCS2 may be positioned at a lower level than the upper surface of the separation structure 146. For example, the upper surface of the second recess part RCS2 may be positioned closer to the upper surface of the second substrate 110 than the upper surface of the separation structure 146. Accordingly, the length of the upper insulation layer 132b along the third direction (Z direction) may be shorter than the length along the third direction (Z direction) from the gate electrode 130 positioned at the uppermost part, of the plurality of gate electrodes 130, to the upper surface of the separation structure 146. Here, the length of the upper insulation layer 132b in the third direction (Z direction) may stand for a distance in the third direction (Z direction) from the upper surface of the gate electrode 130 positioned at the uppermost part, of the plurality of gate electrodes 130, to the upper surface of the upper insulation layer 132b.

In an embodiment of the present inventive concept, since the second recess part RCS2 has a concave shape protruding toward the upper surface of the second substrate 110, the length of the upper insulation layer 132b along the third direction (Z direction) may decrease as the distance from the separation structure 146 increases. For example, the length of the upper insulation layer 132b positioned at the center of the second recess part RCS2 along the third direction (Z direction) may be shorter than the length of the upper insulation layer 132b positioned at the edge of the second recess part RCS2 along the third direction (Z direction). In this case, the length of the upper insulation layer 132b positioned at the center of the second recess part RCS2 along the third direction (Z direction) of the upper insulation layer 132b in the contact region 104 may be the minimum length, but the present inventive concept is not limited thereto.

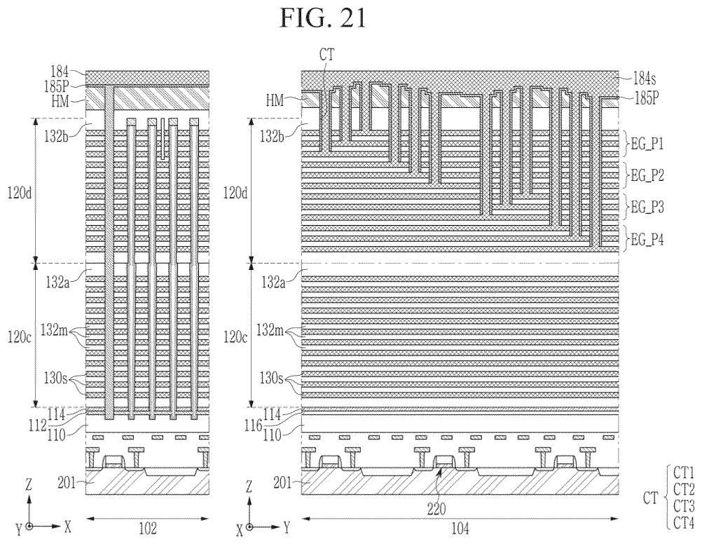

According to an embodiment of the present inventive concept, the sacrificial insulation layer (130s in FIG. 8) and the sacrificial contact part (184s in FIG. 21) of the semiconductor device 10 may be removed, and a plurality of gate contact parts 184 and a plurality of gate electrodes 130 may be simultaneously formed in the removed space. Accordingly, a plurality of gate contact parts 184 and a plurality of gate electrodes 130 may be efficiently formed therein.

In the manufacturing method of the semiconductor device 10 according to an embodiment of the present inventive concept, at least a part of the upper insulation layer 132b may be removed together in the process of removing the hard mask pattern HM that is positioned on the upper insulation layer 132b. In this case, before removing the hard mask pattern HM, a gate spacer 185 and the sacrificial contact part (184s of FIG. 21) may be formed in a plurality of contact holes CT penetrating the upper insulation layer 132b, and a separation structure 146 may be formed. When removing the hard mask pattern HM by using a chemical mechanical polishing process, the gate spacer 185 and the separation structure 146 might not be removed. Therefore, the range to which the upper insulation layer 132b adjacent to the gate spacer 185 is removed from the contact region 104 may be relatively reduced, and the sacrificial contact part (184s of FIG. 21) may be prevented from being removed. In addition, the degree to which the upper insulation layer 132b adjacent to the separation structure 146 is removed from the cell array region 102 may be relatively reduced, thereby preventing the channel structure CH from being exposed. Accordingly, the reliability of the semiconductor device 10 may be increased.

Hereinafter, a semiconductor device according to an embodiment of the present inventive concept will be described with reference to FIGS. 6 and 7.

FIG. 6 is a cross-sectional view illustrating a contact region of a semiconductor device according to an embodiment of the present inventive concept. FIG. 7 is an enlarged cross-sectional view of the P1 region of FIG. 6.

In addition, for a clear understanding, FIG. 6 mainly illustrates the connection structure between a plurality of gate contact parts 184 and a plurality of gate electrodes 130, and the gate spacer 185 is not shown. The detailed connection structure of a plurality of gate contact parts 184, a plurality of gate electrodes 130, and a gate spacer 185 is shown in FIG. 7.

First, referring to FIG. 6, a plurality of gate electrodes 130 according to an embodiment of the present inventive concept may include a plurality of electrode groups EG. For example, a plurality of gate electrodes 130 may include first to fourth electrode groups EG1 to EG4 sequentially stacked from the upper surface of the second substrate 110. The number of gate electrodes 130 provided in each of the plurality of electrode groups EG may be the same.

In addition, a plurality of gate contact parts 184 according to an embodiment of the present inventive concept may include a plurality of contact groups CG. For example, a plurality of gate contact parts 184 may include first contact group CG1 to fourth contact group to CG4 positioned from one side to the other side in the extension direction (e.g., the second direction (Y direction) of the plurality of gate electrodes 130. The number of gate contact parts 184 provided in each of the plurality of contact groups CG may be the same. Although 4 electrode groups EG and 4 contact groups CG are illustrated in FIG. 6, the number of electrode groups EG and the number of contact groups CG are not limited thereto.

A plurality of gate contact parts 184 provided in each of the plurality of contact groups CG1, CG2, CG3, and CG4 may be connected to a plurality of gate electrodes 130 provided in each of the plurality of electrode groups EG. For example, each of plurality of gate contact parts 184 provided in the first contact group CG1 may be connected to plurality of gate electrodes 130 provided in the first electrode group EG1. Each of plurality of gate contact parts 184 provided in the second contact group CG2 may be connected to the plurality of gate electrodes 130 provided in the second electrode group EG2. Each of plurality of gate contact parts 184 provided in the third contact group CG3 may be connected to the plurality of gate electrodes 130 provided in the third electrode group EG3. Each of plurality of gate contact parts 184 provided in the fourth contact group CG4 may be connected to plurality of gate electrodes 130 provided in the fourth electrode group EG4.

The first to fourth contact groups CG4 connected to the first to fourth electrode groups EG1 to EG4, respectively, may have the same connection structure. Hereinafter, with reference to FIG. 7, a connection structure between the first electrode group EG1 and the first contact group CG1 and a connection structure between the second electrode group EG2 and the second contact group CG2 will be described.

Referring further to FIG. 7, the plurality of gate electrodes 130 may include a first electrode group EG1 and a second electrode group EG2 positioned below the first electrode group EG1. The number of gate electrodes 130 provided in the first electrode group EG1 may be the same as the number of gate electrodes 130 provided in the second electrode group EG1.

For example, as illustrated in FIG. 7, the number of gate electrodes 130 included in the first electrode group EG1 and the second electrode group EG2 may be 6, but the present inventive concept is not limited thereto.

In an embodiment of the present inventive concept, a plurality of gate contact parts 184 provided in each of the first and second contact groups CG1 and CG2 may be connected to a plurality of gate electrodes 130 provided in each of the first and second electrode groups EG1 and EG2 in the same connection structure.

For example, as described above, each of a plurality of gate contact parts 184 in the first contact group CG1 may be connected to a plurality of gate electrodes 130 provided in the first electrode group EG1.

Each of plurality of gate contact parts 184 provided in the second contact group CG2 may be connected to plurality of gate electrodes 130 provided in the second electrode group EG2. In this case, the number of gate contact parts 184 provided in the first contact group CG1 and the second contact group CG2 may be the same as each other. For example, as illustrated in FIG. 7, each of the first contact group CG1 and the second contact group CG2 may include six gate contact parts 184. However, the present inventive concept is not limited thereto, and the number of gate contact parts 184 may be a natural number of 2 or more.

In addition, the number of the connection gate electrode 130C according to the direction away from the cell array region 102 in the first contact group CG1 may be the same as the number of the connection gate electrode 130C according to the direction away from the cell array region 102 in the second contact group CG2. For example, in the first contact group CG1, the level of the connection gate electrode 130C may increase in height and then decrease in height depending on the direction away from the cell array region 102. For example, in the first side group CGa, the gate contact part 184, which is nearest to the cell array region 102 among the gate contacts parts 184 of the first side group CGa, is connected to a connection gate electrode 130C that is at a level that is lower than a connection gate electrode 130C that is connected to a gate contact part 184 that is farthest from the cell array region 102 among the gate contact parts of the first side group CGa. In addition, the level of the connection gate electrode 130C may increase in height and then decrease in height depending on the direction away from the cell array region 102 in the second contact group CG2. In this case, the difference in the number of layers below the connection gate electrode 130C that increases or decreases in the first contact group CG1 may be substantially the same as the difference in the number of layers below the connection gate electrode 130C that increases or decreases in the second contact group CG2.

For example, the difference in the number of layers between the highest connection gate electrode 130C in the first contact group CG1 and the lowest connection gate electrode 130C in the first contact group CG1 may be the same as the difference in the number of layers between the highest connection gate electrode 130C in the second contact group CG2 and the lowest connection gate electrode 130C in the second contact CG2. In addition, for example, the differences in the heights of the gate electrodes 130 connected to multiple adjacent gate contact parts 184 in the first contact group CG1 may be the same as the differences in the heights of the gate electrodes 130 connected to each of multiple gate contact parts 184 adjacent to the second contact group CG2.

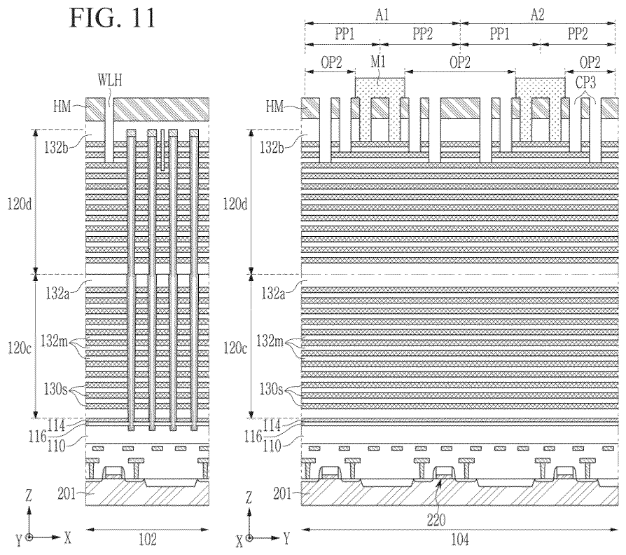

This may result from a process characteristic caused by simultaneously forming a third dummy pattern (CP3 of FIG. 11) in the first region (A1 of FIG. 8) and the second region (A2 of FIG. 8) corresponding to the first contact group CG1 and the second contact group CG2, respectively. In an embodiment of the present inventive concept, the process can be simplified by simultaneously forming a plurality of dummy contact group CPG of the first contact group CG1 and the second contact group CG2.

In an embodiment of the present inventive concept, each of the first and second electrode groups EG1 and EG2 may include an upper group EGa and the lower group EGb that is positioned below the upper group EGa. For example, the upper group EGa of the first electrode group EG1 may be positioned on the lower group EGb of the first electrode group EG1. In addition, the lower group EGb of the second electrode group EG2 may be positioned below the upper group EGa of the first electrode group EG1, and the upper group EGa of the second electrode group EG2 may be positioned on the lower group EGb of the second electrode group EG2.

The number of a plurality of gate electrodes 130 included in each of the lower group EGb and the upper group EGa may be the same as one another. For example, as illustrated in FIG. 7, the number of gate electrodes 130 included in the upper group EGa and the lower group EGb of the first electrode group EG1 and the number of gate electrodes 130 included in the upper group EGa and the lower group EGb of the second electrode group EG2 may be three, respectively, but the present inventive concept is not limited thereto.

Hereinafter, for convenience of explanation, the number of gate electrodes 130 included in each of the lower group EGb and the upper group EGa will be referred to as the number of units. For example, FIG. 7 may illustrate a case in which the number of units is 3.

In an embodiment of the present inventive concept, each of the first and the second contact groups CG1 and CG2 may include a first side group CGa connected to the upper group EGa and the second side group CGb connected to the lower group EGb.

For example, the first side group CGa of the first contact group CG1, which is connected to the upper group EGa of the first electrode group EG1, the second side group CGb of the first contact group CG1, which is connected to the lower group EGb of the first electrode group EG1, a first side group CGa of the second contact group CG2, which is connected to the upper group EGa of the second electrode group EG2, and a second side group CGb of the second contact group CG2, which is connected to the lower group EGb of the second electrode group EG2, may be included. In addition, the first side group CGa may be positioned on one side in the extension direction of the plurality of gate electrodes 130, and the second side group CGb may be positioned on the other side in the extension direction of the plurality of gate electrodes 130. For example, the first side group CGa and the second side CGb may sequentially arranged in the second direction (Y-direction). For example, the first side group CGa of the first contact group CG1, the second side group CGb of the first contact group CG1, the first side group CGa of the second contact group CG2, and the second side group CGb of the second contact group CG2 may be sequentially positioned from one side to the other side of the gate stacking structure 120 in the extending direction of a plurality of gate electrodes 130.

In embodiment of the present inventive concept, the connection structure between the upper group EGa and the first side group CGa and the connection structure between the lower group EGb and the second side group CGb may have a roughly symmetrical structure. For example, with respect to a line extending between the first side group CGa and the second side group CGa, a length of the gate contact parts 184 of the first side group CGa decreases as the line is approached, and a length of the gate contact parts 184 of the second side group CGb decreases as the line is approached. Further to that example, the gate contacts 184 of the second side group CGb have longer lengths in the third direction (Z-direction) than lengths of the gate contacts 184 of the first side group CGa in the third direction (Z-direction).

For example, in the first side group CGa and the second side group CGb, the difference in the number of layers of the plurality of gate electrodes 130 connected to the plurality of gate contact parts 184 may be the same. For example, the difference in the number of layers between the highest connection gate electrode 130C in the first side group CGa and the lowest connection gate electrode 130C in the first side group CGa may be the same as the difference in the number of layers between the highest connection gate electrode 130C in the second side group CGb and the lowest connection gate electrode 130C in the second side group CGb. In addition, for example, the difference in the heights the gate electrodes 130 connected to the plurality of gate contact parts 184 in the first side group CGa may be the same as the difference in the heights of the gate electrodes 130 connected to each of gate contact parts 184 in the second side group CGb.

In addition, in the first side group CGa and the second side group CGb, the number of layers below a plurality of gate electrodes 130 connected to a plurality of gate contact parts 184 may decrease sequentially as the distance from the boundary between the first side group CGa and the second side group CGb increases. In other words, a plurality of gate contact parts 184 provided in the first side group CGa may be connected to a plurality of gate electrodes 130 positioned relatively lower as a distance from the boundary between the first side group CGa and the second side group CGb increases. In the first side group CGa and the second side group CGb, as the distance from the boundary between the first side group CGa and the second side group CGb increases, the number of gate electrodes 130 passing through the plurality of gate contact parts 184 may increase sequentially.

For example, as shown in FIG. 7, in the first side group CGa and the second side group CGb, as the distance from the boundary between the first side group CGa and the second side group CGb increases, the number of layers (e.g., gate electrodes 130) below gate electrodes 130 connected to adjacent gate contact parts 184 may decrease by one layer. However, the present inventive concept is not limited thereto, and as the distance from the boundary between the first side group CGa and the second side group CGb increases, the number of layers below gate electrodes 130 connected to the adjacent gate contact parts 184 may increase by two or more layers.

In an embodiment of the present inventive concept, in the first side group CGa and the second side group CGb, the number of passing gate electrode 130R through which each of a plurality of gate contact parts 184 penetrate may sequentially increase as the distance from the boundary between the first side group CGa and the second side group CGb increases. In addition, the length of plurality of gate contact parts 184 provided in the first side group CGa and the second side group CGb may increase sequentially as they move away from the boundary between the first side group CGa and the second side group CGb. In this case, the first distance DD1 along the third direction (Z direction) between bottom surfaces of the adjacent gate contact parts 184 in the first side group CGa may be substantially the same as the second distance DD2 between the bottom surfaces of the adjacent gate contact parts 184 in the second side group CGb.

However, the present inventive concept is not limited thereto, and in the first side group CGa and second side group CGb, as the distance from the boundary between the first side group CGa and the second side group CGb increases, the number of layers below the gate electrodes 130 connected to a plurality of gate contact parts 184 may sequentially increase. In this case, the number of layers below a connection gate electrode 130C, to which a plurality of gate contact parts 184 are connected, in the second side group CGb may be higher than the number of layers below a connection gate electrode 130C, to which a plurality of gate contact parts 184 are connected, in the first side group CGa.

In an embodiment of the present inventive concept, in each of the first and second contact groups CG2, the number of layers below a connection gate electrode 130C, to which a plurality of gate contact parts 184 are connected, in second side group CGb may be lower than the number of layers below a connection gate electrode 130C, to which a plurality of gate contact parts 184 are connected, in the first side group CGa. For example, a level of any one of the connection gate electrodes 130C, to which a plurality of gate contact parts 184 are connected, in the second side group CGb may be lower than a level of each of the connection gate electrodes 130C, to which a plurality of gate contact parts 184 are connected in the first side group CGa. For example, the highest connection gate electrode 130C in the second side group CGb may be lower than the lowest connection gate electrode 130C in the first side group CGa.

In an embodiment of the present inventive concept, the number of layers below the connection gate electrode 130C connected to the gate contact parts 184 in the first side group CGa of the second contact group CG2 may be lower than the number of layers below the connection gate electrode 130C connected to the gate contact parts 184 in the second side group CGb of the first contact group CG1. For example, the number of layers below any one of the connection gate electrodes 130C, to which the gate contact parts 184 is connected, in the first side group CGa of the second contact group CG2 may be lower than the number of layers below of each of the connection gate electrodes 130C, to which the gate contact parts 184 is connected, in the second side group CGb of the first contact group CG1. For example, the highest connection gate electrode 130C in the first side group CGa of the second contact group CG2 may be lower than the lowest connection gate electrode 130C in the second side group CGb of the first contact group CG1. In this case, the length of the gate contact parts 184 provided in the first side group CGa of the second contact group CG2 may be greater than the length of the gate contact parts 184 provided in the second side group CGb of the first contact group CG1.

In an embodiment of the present inventive concept, the minimum distance between the gate contact parts 184 provided in the second side group CGb and the gate contact parts 184 provided in the first side group CGa may be greater than the minimum distance between the adjacent gate contact parts 184. For example, the third length D3 between the gate contact parts 184 positioned in the first side group CGa and the gate contact parts 184 positioned in the second side group CGb may be greater than the fourth length D4 between the adjacent gate contact parts 184 provided in the first side group CGa or the second side group CGb. However, the present inventive concept is not limited thereto, and the third length D3 between the gate contact part 184 positioned in the first side group CGa and the gate contact part 184 positioned in the second side group CGb which are adjacent to each other may be substantially equal to the fourth length D4 that is between the adjacent gate contact parts 184 provided in the first side group CGa or the second side group CGb.

According to an embodiment of the present inventive concept, the connection structure of the third electrode group EG3 and the third contact group CG3, and the connection structure of the fourth electrode group EG4 and the fourth contact group CG4 are substantially the same as the connection structure of the first electrode group EG1 and the first contact group CG1, and the connection structure of the second electrode group EG2 and the second contact group CG2, so descriptions thereof will be omitted.

In an embodiment of the present inventive concept, the connections between a plurality of gate contact parts 184 and a plurality of gate electrodes 130, in a connection structure, has a consistent arrangement, as discussed above, but connection structures may be different from one another. For example, the connection structure between the upper group EGa and the first side group CGa and the connection structure between the lower group EGb and the second side group CGb may be different from each other. In addition, the length of the plurality of gate contact parts 184 along the third direction (Z direction) may increase or decrease as a distance from the cell array region 102 increases. In this case, the technical idea according to an embodiment of the present inventive concept may be applied.

Hereinafter, a method of manufacturing a semiconductor device according to an embodiment of the present inventive concept will be described with reference to FIG. 8 to FIG. 25.

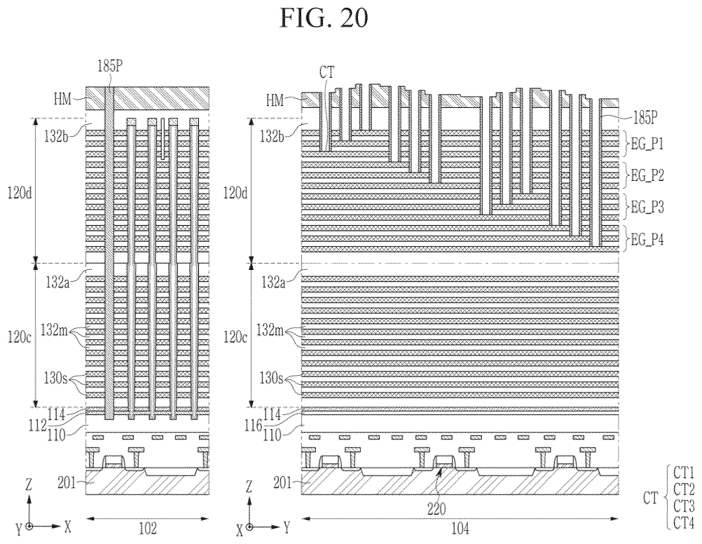

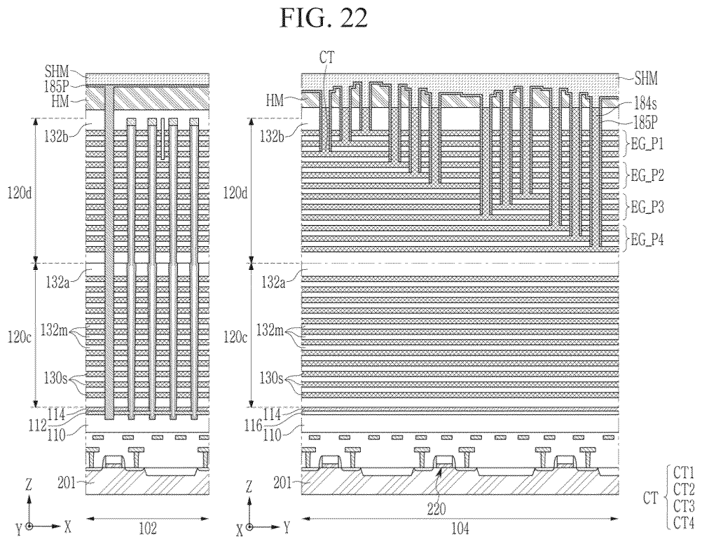

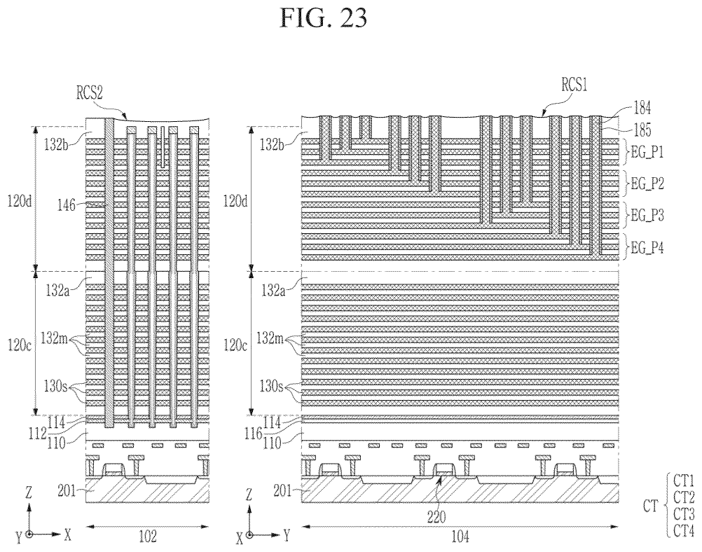

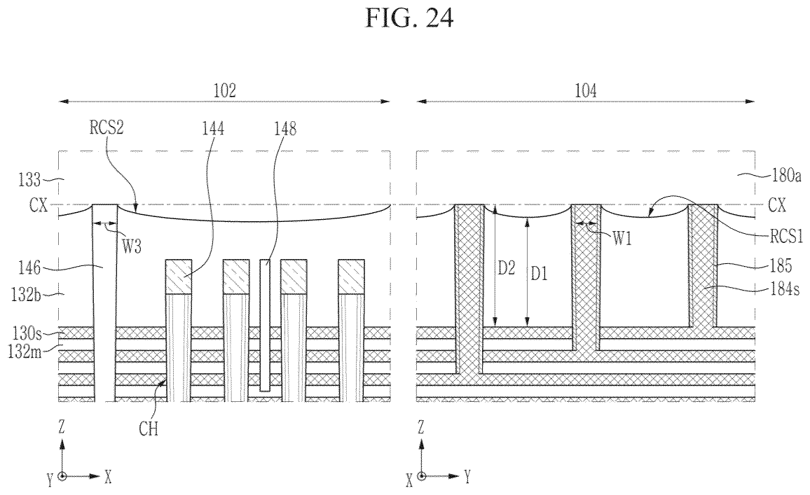

FIGS. 8 to 19, 21, and 23 to 25 are process cross-sectional views sequentially showing a method of manufacturing a semiconductor device according to an embodiment of the present inventive concept. FIGS. 20 and 22 are cross-sectional views illustrating a semiconductor device according to embodiments of the present inventive concept. FIG. 24 is an enlarged cross-sectional view illustrating a part of a cell array region and a part of a contact region of FIG. 23. In FIG. 8 to FIG. 25, for convenience, only a part of cell array region 102 and a part of the contact region 104 are illustrated for convenience. Hereinafter, a method of manufacturing a plurality of gate contact parts 184 and a separation structure 146 of the semiconductor device 10 according to an embodiment of the present inventive concept will be mainly described.

Referring to FIG. 8, stacking structures 120c and 120d are formed on the circuit region 200 including the peripheral circuit structure. First, the first stacking structure 120c, which is a lower structure, may be formed by alternately stacking the sacrificial insulation layer 130s and the interlayer insulation layer 132m. An intermediate insulation layer 132a may be positioned on an uppermost part of the first stacking structure 120c. A second substrate 110, a horizontal insulation layer 116, a second horizontal conductive layer 114, and the like may be further formed between the circuit region 200 and the first stacking structure 120c.

A second substrate 110, a horizontal insulation layer 116, a second horizontal conductive layer 114, and the like may be further formed between the circuit region 200 and the first stacking structure 120c. For example, the interlayer insulation layer 132m may include silicon oxide, silicon nitride, silicon oxynitride, low dielectric constant material, and the sacrificial insulation layer 130s may include at least one of silicon, silicon oxide, silicon carbide, and/or silicon nitride. A sacrificial insulation layer 130s may include a material having etching selectivity with respect to the interlayer insulation layer 132m.

Subsequently, the second stacking structure 120d, which is an upper structure, may be formed by alternately stacking the sacrificial insulation layer 130s and the interlayer insulation layer 132m on the first stacking structure 120c. An upper insulation layer 132b may be formed on the second stacking structure 120d. A method of manufacturing the sacrificial insulation layer 130s, the interlayer insulation layer 132m, the upper insulation layer 132b, and the like of the second stacking structure 120d may be the same as the sacrificial insulation layer 130s, the interlayer insulation layer 132m, the intermediate insulation layer 132a, and the like, respectively, of the first stacking structure 120c, and a description thereof will be omitted.

Although the stacking structures 120c and 120d are formed of two stacking structures in the drawings, the present inventive concept is not limited thereto, and the stacking structures 120c and 120d may be formed of one stacking structure or may include three or more stacking structures.

The sacrificial insulation layer 130s may be a layer that is replaced with a gate electrode 130 of FIG. 1 in a subsequent process. For example, the sacrificial insulation layer 130s may be formed to correspond to a portion in which the gate electrode 130 of FIG. 1 is to be formed.

Subsequently, a channel structure CH penetrating the stacking structures 120c and 120d may be formed in the cell array region 102. The channel structure CH may extend to the third direction (Z direction). The channel structure CH may be formed by sequentially forming a gate dielectric layer 150, a channel layer 140, and a core insulation layer 142 in the channel hole after forming a channel hole penetrating the stacking structures 120c and 120d, and then forming a channel pad 144 on the gate dielectric layer 150, the channel layer 140, and the core insulation layer 142.

Subsequently, a hard mask pattern HM may be formed on the second stacking structure 120d, and first dummy pattern CP1 may be formed to penetrate the hard mask pattern HM and the upper insulation layer 132b.

First, a hard mask pattern HM may be formed on the upper insulation layer 132b in the cell array region 102 and the contact region 104. Since the hard mask pattern HM serves as a mask pattern in a repeated etching process that is in a subsequent process, the hard mask pattern HM may be formed to have sufficient thickness in consideration of the reduced thickness that will occur in the repeated etching process. The hard mask pattern HM may include a material having etching selectivity with respect to sacrificial insulation layer 130s, the interlayer insulation layer 132m, and the upper insulation layer 132b.

Subsequently, the hard mask pattern HM may be patterned and the exposed upper insulation layer 132b may be etched to form first dummy patterns CP1 and a separation hole WLH. For example, first dummy patterns CP1 may be formed by patterning a hard mask pattern HM in the cell array region 102 and etching the exposed upper insulation layer 132b. In addition, a separation hole WLH can be formed by patterning a hard mask pattern HM in the contact region 104 and etching the exposed upper insulation layer 132b. The first dummy patterns CP1 and the separation hole WLH may be vertical etching structures formed by etching the hard mask pattern HM and the upper insulation layer 132b in the third direction (Z direction).

Here, the first dummy patterns CP1 may refer to a hole pattern in which a plurality of gate contact parts 184 of FIG. 1 are formed.

The first dummy patterns CP1 and the separation hole WLH may be formed by using an etching process and the sacrificial insulation layer 130s of top portion as an etch stop layer. Accordingly, the upper surface of the sacrificial insulation layer 130s may be exposed. Here, the first dummy patterns CP1 are hole-shaped patterns for forming a plurality of gate contact parts 184 and may be positioned in the contact region 104. In addition, the separation hole WLH is intended to form a separation structure 146 and may be positioned in the cell array region 102.

The same number of first dummy patterns CP1 may be formed in regions A1 and A2, respectively. For example, six first dummy patterns CP1 may be formed in each of the first region A1 and the second region A2. In addition, the same number of first dummy patterns CP1 may be formed in the zones PP1 and PP2, respectively. For example, three first dummy patterns CP1 may be formed in each of a first side zone PP1 and the second side zone PP2. Here, the first region A1 and the second region A2 may be regions where the first contact group CG1 and the second contact group CG2 are formed, respectively.

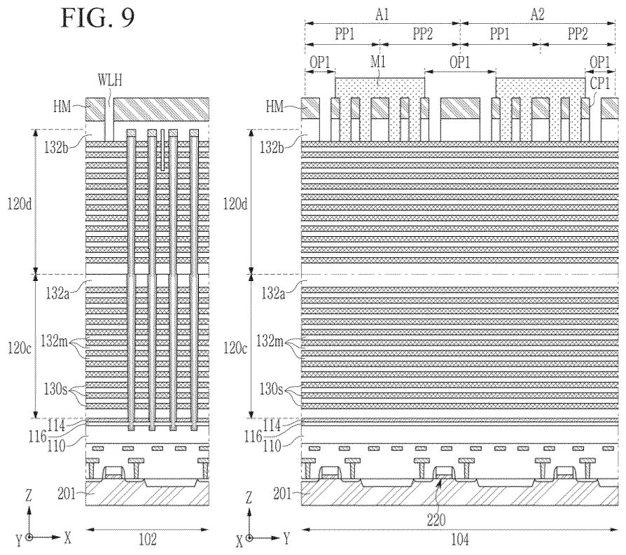

In addition, the first side zone PP1 and the second side zone PP2 may be regions where the first side group CGa and the second side group CGb are formed, respectively. Hereinafter, referring to FIG. 9 to FIG. 12, a process of forming first to third dummy patterns CP1 to CP3 using the first mask pattern M1 will be described.

Referring to FIG. 9, a first mask pattern M1 including a first open part OP1 is formed on the hard mask pattern HM. The first mask pattern M1 may be a photoresist pattern. The first mask pattern M1 may be positioned in each of the regions A1 and A2. For example, the first mask pattern M1 may be positioned in the first region A1 and the second region A2, respectively. The first open part OP1 may be formed between the regions A1 and A2. A first mask pattern M1 might not be formed on the hard mask pattern HM positioned in the cell array region 102.

As the first open part OP1 is formed, the same number of first dummy patterns CP1 may be exposed in each of the zones PP1 and PP2. For example, one first dummy pattern CP1 may be exposed in each of the first side zone PP1 of the first region A1, the second side zone PP2 of the first region A1, the first side zone PP1 of the second region A2, and the second side zone PP2 of the second region A2. In this case, the exposed first dummy pattern CP1 may be symmetrically positioned with respect to the boundary between the first side zone PP1 and the second side zone PP2. In addition, the shape and arrangement relationship of the exposed first dummy pattern CP1 may be substantially the same when compared to those in the first region A1 and the second region A2.

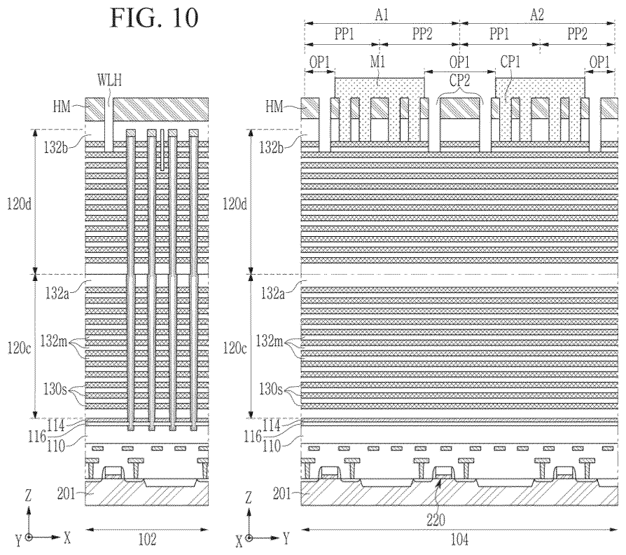

Referring to FIG. 10, second dummy patterns CP2 are formed by etching the first dummy patterns CP1 exposed to the respective zones PP1 and PP2 using the first mask pattern M1 as a mask. For example, second dummy patterns CP2 may be formed by partially etching one sacrificial insulation layer 130s and one interlayer insulation layer 132m in the exposed first dummy patterns CP1. As the second dummy pattern CP2 is formed, the sacrificial insulation layer 130s may be exposed. The process of forming the second dummy patterns CP2 may be formed by various etching processes. For example, the second dummy patterns CP2 may be formed by a plasma etching process composed of a vertical surface or an inclined surface but are not limited thereto. The second dummy patterns CP2 may be formed by extending the first dummy patterns CP1 downward.

Here, the second dummy patterns CP2 may refer to a hole pattern in which a plurality of gate contact parts 184 of FIG. 1 are formed.

The second dummy pattern CP2 may be positioned at both sides of the first mask pattern M1 in the first region A1 and the second region A2, respectively. The second dummy pattern CP2 may have the same structure in the first region A1 and the second region A2. In addition, the second dummy pattern CP2 may be symmetrically positioned with respect to the boundary between the first side zone PP1 and the second side zone PP2.

The bottom surface of the second dummy pattern CP2 may be positioned at a lower level than the bottom surfaces of the first dummy patterns CP1. For example, the distance between the bottom surfaces of the second dummy patterns CP2 and the bottom surfaces of the first dummy patterns CP1 may be substantially equal to the distance between adjacent sacrificial insulation layer 130s.

In an embodiment of the present inventive concept, in a process of forming the second dummy pattern CP2, the separation hole WLH positioned in the cell array region 102 may be expanded downward. For example, the separation hole WLH may be extended downward by partially etching one layer of sacrificial insulation layer 130s and one layer of interlayer insulation layer 132m that are exposed by the separation hole WLH.

In this case, a part of the first mask pattern M1 may be etched together. However, even if a part of the first mask pattern M1 is etched by a repeated etching process, the first dummy patterns CP1 might not be exposed because the first mask pattern M1 is formed to have a sufficient thickness.

Referring to FIG. 11, the first dummy pattern CP1 may be exposed by expanding the first open portion OP1, and the third dummy pattern CP3 may be formed by downwardly expanding the exposed first dummy pattern CP1 and the second dummy pattern CP2.

First, the first open portion OP1 is expanded to form a second open portion OP2. For example, both sides of the first mask pattern M1 may be etched in the third direction (Z direction) to expand the first open part OP1. Accordingly, the same number of first dummy patterns CP1 may be additionally exposed in respective zones PP1 and PP2 through the expanded second open part OP2. For example, one first dummy pattern CP1 may be additionally exposed in each of the first side zone PP1 of the first region A1, the second side zone PP2 of the first region A1, the first side zone PP1 of the second region A2, and the second side zone PP2 of the second region A2.

Here, a third dummy patterns CP3 may refer to a hole pattern in which a plurality of gate contact parts 184 of FIG. 1 are formed.

The additionally exposed first dummy patterns CP1 may be positioned adjacent to second dummy patterns CP2, respectively. For example, the additionally exposed first dummy patterns CP1 may be positioned on both sides of the first mask pattern M1 in the first region A1 and the second region A2, respectively. The shape and arrangement relationship of the exposed first dummy pattern CP1 may be substantially the same when compared to those in the first region A1 and the second region A2. At this time, the additionally exposed first dummy patterns CP1 may be positioned symmetrically based on the boundary between the first side zone PP1 and the second side zone PP2. This may be because both sides of the first mask pattern M1 are equally etched to form the second open part OP2.

Subsequently, a third dummy pattern CP3 may be formed by etching the first dummy patterns CP1 and the second dummy patterns CP2 that are exposed to the respective zones PP1 and PP2 by using the first mask pattern M1 as a mask. For example, one layer of sacrificial insulation layer 130s and one layer of interlayer insulation layer 132m may be partially etched in the exposed first dummy patterns CP1 and second dummy patterns CP2. The process of forming the third dummy patterns CP3 may be formed by various etching processes. For example, the third dummy patterns CP3 may be formed by a plasma etching process and composed of a vertical surface or an inclined surface but are not limited thereto.

In an embodiment of the present inventive concept, in a process of forming the third dummy pattern CP3, the separation hole WLH positioned in the cell array region 102 may be extended downward. For example, by partially etching one layer of sacrificial insulation layer 130s and one layer of interlayer insulation layer 132m that are exposed by the separation hole WLH, the separation hole WLH may be extended downward.

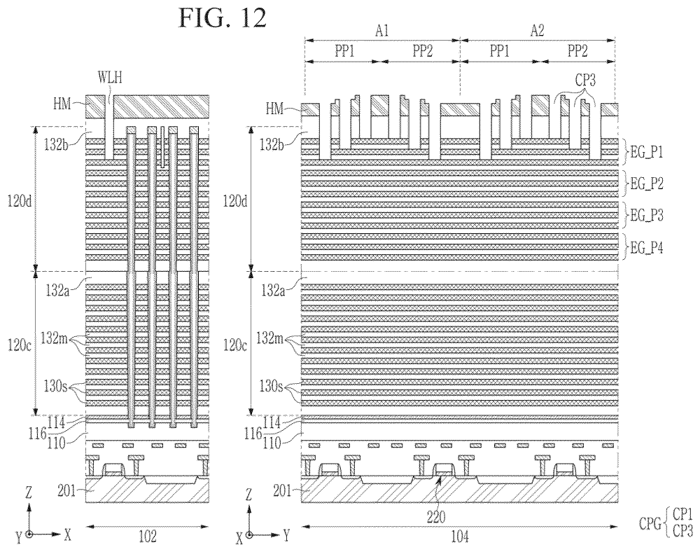

Referring to FIG. 12, the first mask pattern M1 may be removed to form a plurality of dummy contact groups CPG including the first side zone PP1 and the second side zone PP2 in an upper sacrificial insulation layer group (e.g., a first sacrificial insulation layer group EG_P1).

In an embodiment of the present inventive concept, a plurality of dummy contact groups CPG formed in each of the regions A1 and A2 may have the same structure as each other. In addition, a plurality of dummy contact groups CPG may include a first region A1 and a second region A2.

In an embodiment of the present inventive concept, a plurality of dummy contact groups CPG formed in each of the regions A1 and A2 may have the same structure as each other.

For example, a plurality of dummy contact groups CPG that are formed in the first region A1 and the second region A2 may have the same shape as each other. For example, a plurality of dummy contact groups CPG provided in the first side zone PP1 of the first region A1 and a plurality of dummy contact groups CPG provided in the first side zone PP1 of the second region A2 may have the same shape as each other.

In addition, a plurality of dummy contact groups CPG in the second side zone PP2 of the first region A1 and a plurality of dummy contact groups CPG in the second side zone PP2 of the second region A2 may have the same shape as each other. In addition, the sacrificial insulation layer 130s may include the plurality of sacrificial insulation layer groups EG_P1, EG_P2, EG_P3 and EG_P4. For example, the sacrificial insulation layer 130s may include the first to fourth sacrificial insulation layer groups EG_P1 to EG_P4 that are sequentially stacked on each other. The number of sacrificial insulation layers 130s provided in each of the first to fourth sacrificial insulation layer groups EG_P1 to EG_P4 may be the same as one another. For example, three sacrificial insulation layers 130s may be provided in each of the first to fourth sacrificial insulation layer groups EG_P1 to EG_P4.

In this case, a plurality of dummy contact groups CPG formed in each of the regions A1 and A2 may expose the upper surface of the upper sacrificial insulation layer group (e.g., the first sacrificial insulation layer group EG_P1). For example, each of dummy contact groups CPG formed in each region A1 and A2 may expose the upper surface of the sacrificial insulation layer 130s positioned in different layers provided in each of the first to fourth sacrificial insulation layer groups EG_P1 to EG_P4. Here, the upper sacrificial insulation layer group (e.g., the first sacrificial insulation layer group EG_P1 may be a sacrificial insulation layer 130s that is exposed by the third dummy pattern CP3.

Hereinafter, the upper sacrificial insulation layer group will be referred to as the first sacrificial insulation layer group EG_P1.

In an embodiment of the present inventive concept, each of the first to fourth sacrificial insulation layer groups EG_P1 to EG_P4 may correspond to the upper group EGa and lower group EGb of the first electrode group EG1 and the upper group EGa and the lower group EGb of the second electrode group EG2, respectively. Hereinafter, for convenience of description, the number of sacrificial insulation layers 130s included in each of the first to fourth sacrificial insulation layer groups EG_P1 to EG_P4 will be referred to as a unit number. For example, in the case where the number of units is 3, each of the first to fourth sacrificial insulation layer groups EG_P1 to EG_P4 may include three sacrificial insulation layers 130s. In this case, three dummy contact groups CPG may be formed in each of the zones PP1 and PP2.

In an embodiment of the present inventive concept, a plurality of dummy contact groups CPG may be positioned symmetrically with respect to a boundary between the first side zone PP1 and the second side zone PP2. For example, the depth of the plurality of dummy contact groups CPG may increase as the distance from the boundary between the first side zone PP1 and the second side zone PP2 increases. This is because the process of exposing the first dummy patterns CP1 by etching both sides of the first mask pattern M1 in the third direction (Z direction) and the process of etching the exposed first dummy pattern CP1 are repeatedly performed.

Accordingly, the number of sacrificial insulation layers 130s included in the first sacrificial insulation layer group EG_P1 may correspond to the number of a plurality of dummy contact groups CPG formed in each of the zones PP1 and PP2.

In an embodiment of the present inventive concept, the first mask pattern M1 is removed to form a plurality of dummy contact groups CPG, but the present inventive concept is not limited thereto. For example, a process of removing the first mask pattern M1 and etching the exposed first dummy patterns CP1 and the third dummy patterns CP3 may be further included. For example, one layer of sacrificial insulation layer 130s and one layer of interlayer insulation layer 132m may be partially etched in the exposed first dummy patterns CP1 and third dummy patterns CP3.

In an embodiment of the present inventive concept, three dummy contact groups CPGs are formed in the first side zone PP1 and the second side zone PP2 of the first region A1, and the first side zone PP1 and the second side zone PP2 of the second region A2, but the present inventive concept is not limited thereto. For example, four or more dummy contact groups CPGs may be provided in each of the first side zone PP1 and the second side zone PP1 of the first region A1, the first side zone PP1 and the second side zone PP2 of the second region A2. In this case, the step of additionally exposing the first dummy patterns CP1 by partially removing the first mask pattern M1 in the third direction (Z direction) and the step of etching the exposed first dummy pattern CP1 may be repeated several times. The first mask pattern M1 is formed at a position where the first dummy patterns CP1 are not exposed, but as the open part of the first mask pattern M1 is expanded, the first dummy patterns CP1 are sequentially exposed. Accordingly, the first dummy patterns CP1 may be expanded to various depths. In addition, two dummy patterns may be formed in each of the first side zone PP1 and the second side zone PP2 of the first region A1 and the first side zone PP1 and the second side zone PP2 of the second region A2.

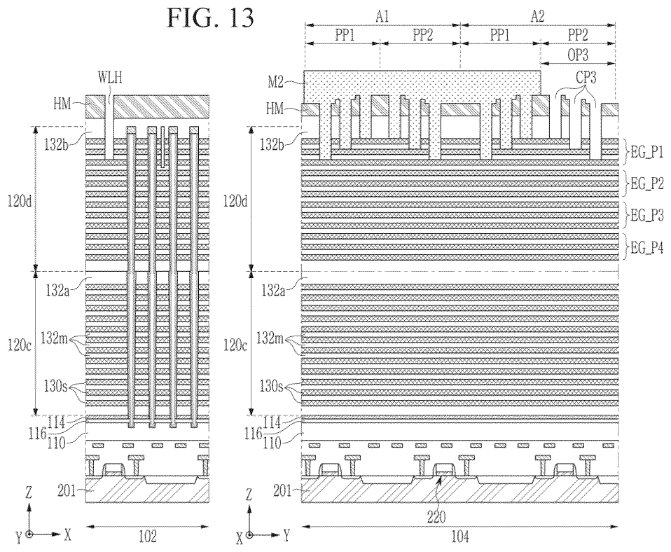

Hereinafter, referring to FIGS. 13 to 16, a process for forming a plurality of contact holes CT having different depths by using the second mask pattern M2 will be described.

Referring to FIG. 13, a second mask pattern M2 including a third open part OP3 may be formed on the hard mask pattern HM. The second mask pattern M2 may be a photoresist pattern. The second mask pattern M2 may extend in an extending direction of a plurality of sacrificial insulation layers 130s. The second mask pattern M2 may be positioned at one side in the extending direction of the plurality of sacrificial insulation layers 130s. The second mask pattern M2 might not be formed on the hard mask pattern HM positioned in the cell array region 102.

The third open part OP3 of the second mask pattern M2 may expose any one zone unit. For example, the third open part OP3 may expose the third dummy pattern CP3 which is positioned in the second side zone PP2 of the second region A2. The third open part OP3 of the second mask pattern M2 may expose the third dummy pattern CP3 having different depths from each other.

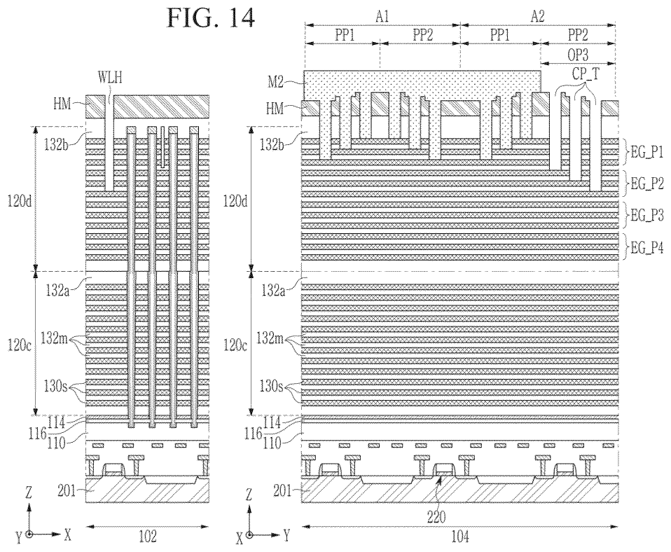

Referring to FIG. 14, the dummy contact holes CT_P may be formed by etching the exposed dummy contact group CPG by using the second mask pattern M2 as a mask, and an exposed separation hole WLH may be expanded downward.

In an embodiment of the present inventive concept, the process of forming the dummy contact holes CT_P in the second side zone PP2 of the second region A2 may be formed by etching the sacrificial insulation layer 130s corresponding to the number of units. For example, the process of forming the dummy contact holes CT_P may be formed by etching the sacrificial insulation layers 130s having the same number of layers as the number of sacrificial insulation layers 130s included in the first sacrificial insulation layer group EG_P1. For example, when the number of units is 3, dummy contact holes CT_P may be formed by partially etching the sacrificial insulation layer 130s of 3 layers and the interlayer insulation layer 132m of 3 layers in the dummy contact group CPG of the second side zone PP2 of the second region A2. The dummy contact holes CT_P may be formed by extending a dummy contact group CPG to a lower portion of the sacrificial insulation layer 130s.

In this case, the separation hole WLH may be etched together downward. For example, a part of the sacrificial insulation layer 130s and a part of the interlayer insulation layer 132m positioned on the bottom surface of the separation hole WLH may be etched together to expand the separation hole WLH downward.

Accordingly, the upper surface of the second sacrificial insulation layer group EG_P2 may be exposed by the dummy contact holes CT_P formed in the second side zone PP2 of the second region A2. The dummy contact holes CT_P may penetrate the first sacrificial insulation layer group EG_P1. Here, each of the first and second sacrificial insulation layer groups EG_P1 and EG_P2 may correspond to an upper group (EGa of FIG. 7) and a lower group (EGb of FIG. 7) of the first electrode group EG1.

In addition, as the dummy contact group CPG that is exposed by the third open part OP3 is simultaneously etched, the difference in the number sacrificial insulation layer 130s that are exposed by the dummy contact hole CT_P may be substantially equal to the difference in the number of sacrificial insulation layer 130s that are exposed by the dummy contact group CPG. For example, the difference in the number of layers of the sacrificial insulation layer 130s exposed by the adjacent dummy contact hole CT_P may be the same as the difference in the number of layers of the sacrificial insulation layer 130s exposed by the adjacent third dummy pattern CP3.

The process of forming the dummy contact holes CT_P may be formed by various etching processes. As an example, dummy contact holes CT_P may be formed by a plasma etching process to be formed as a vertical surface or an inclined surface but are not limited thereto.

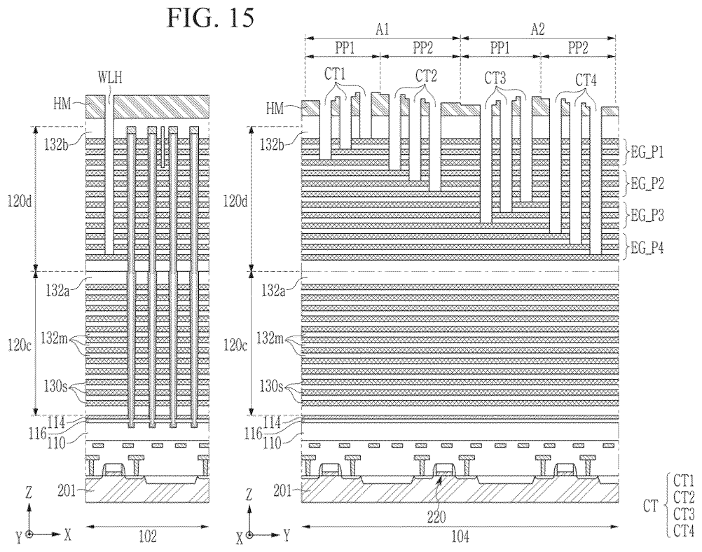

Referring to FIG. 15, one side of the second mask pattern M2 may be etched in the third direction (Z direction) to expand the third open part OP3. The extended open part of the second mask pattern M2 may expose any one zone unit. For example, the third open part OP3 may be extended to open the first side zone PP1 of the second region A2.

Accordingly, the dummy contact group CPG may be additionally exposed through the extended open part. For example, a dummy contact group CPG positioned in the first side zone PP1 of the second region A2 may be additionally exposed.

Then, the exposed dummy contact group CPG may be etched by using the second mask pattern M2 as a mask. The process of etching the dummy contact group CPG exposed in the first side zone PP1 of the second region A2 may be formed by etching the sacrificial insulation layer 130s corresponding to the number of units. For example, the process of forming the dummy contact holes CT_P may be formed by etching the sacrificial insulation layers 130s having the same number of layers as the number of sacrificial insulation layers 130s included in the first sacrificial insulation layer group EG_P1. For example, when the number of units is 3, dummy contact holes CT_P may be formed by partially etching the sacrificial insulation layer 130s of 3 layers and the interlayer insulation layer 132m of 3 layers in the dummy contact group CPG of the first side zone PP1 of the second region A2.

Next, the step of etching one side of the second mask pattern M2 in the third direction (Z direction) to further expose the zone unit and then etching the exposed dummy contact group CPG may be repeated several times.

As the pen part of the second mask pattern M2 is extended, the dummy contact groups CPG of each of zones PP1 and PP2 may be sequentially exposed, and the exposed dummy contact group CPG may be etched. In this case, the dummy contact holes CT_P formed in the respective zones PP1 and PP2 may be etched together.

Accordingly, contact holes CT having different depths may be formed. For example, in the first region A1, the upper surface of the first sacrificial insulation layer group EG_P1 may be exposed by the first contact hole CT1, and the upper surface of the second sacrificial insulation layer group EG_P2 may be exposed by the second contact hole CT2. In addition, in the second region A2, the upper surface of the third sacrificial insulation layer group EG_P3 may be exposed by the third contact hole CT3, and the upper surface of the fourth sacrificial insulation layer group EG_P4 may be exposed by the fourth contact hole CT4. Here, the first contact hole CT1 may be contact holes CT formed in the first side zone PP1 of the first region A1. The second contact hole CT2 may be contact holes CT formed in the second side zone PP2 of the first region A1. The third contact hole CT3 may be contact holes CT formed in the first side zone PP1 of the second region A2. The fourth contact hole CT4 may be contact holes CT formed in the second side zone PP2 of the second region A2.

In an embodiment of the present inventive concept, the contact holes CT may have different depths from one another. For example, the depth of the contact holes CT provided in the first region A1 may be shallower than the depth of the contact holes CT provided in the second region A2. For example, the depth of any one of the contact holes CT provided in the second region A2 may be longer than the depth of each of the contact holes CT provided in the first region A1. In addition, the depth of the contact holes CT provided in the first side zone PP1 may be shallower than the depth of the contact holes CT provided in the second side zone PP2. In an embodiment of the present inventive concept, in the process of forming the contact holes CT, the separation hole WLH may be extended downward. For example, a part of the sacrificial insulation layer 130s and a part of the interlayer insulation layer 132m positioned on the bottom surface of the separation hole WLH may be etched together to expand the separation hole WLH downward.

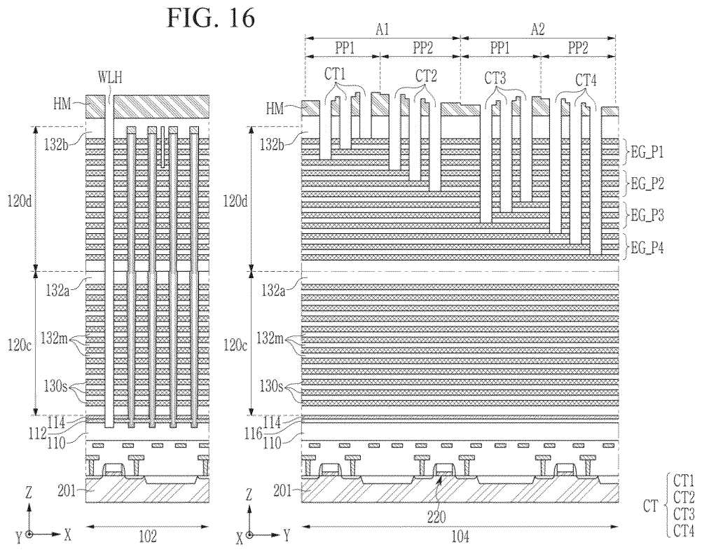

Referring to FIG. 16, contact holes CT exposing the sacrificial insulation layer 130s of the first stacking structure 120c may be further formed. In this case, the separation hole WLH may be extended downward. For example, a part of the sacrificial insulation layer 130s and a part of the interlayer insulation layer 132m positioned on the bottom surface of the separation hole WLH may be etched together to expand the separation hole WLH downward. Accordingly, the separation hole WLH may penetrate the stacking structure 120c and 120d.

In addition, in an embodiment of the present inventive concept, an additional process of etching the separation hole WLH may be further performed so that the separation hole WLH penetrates the horizontal insulation layer 116 and the second horizontal conductive layer 114 and penetrates at least a part of the second substrate 110. Accordingly, the separation hole WLH may penetrate the stacking structures 120c and 120d, the horizontal insulation layer 116 and 112. In addition, the side surface of the horizontal insulation layer 116 may be exposed. In an embodiment, the first horizontal conductive layer 112 may be formed by removing at least a part of the horizontal insulation layer 116 exposed by the separation hole WLH.

Hereinafter, referring to FIGS. 17 to 25, a process of removing a hard mask pattern HM by using a chemical mechanical polishing process and forming a plurality of gate contact parts 184 and a plurality of gate electrodes 130 will be described.

Referring to FIG. 17, a dummy gate spacer 185P may be formed in a plurality of contact holes CT and the separation hole WLH. For example, a dummy gate spacer 185P may be formed on the bottom surface and sidewall of a plurality of contact holes CT, the lower surface and sidewall of the separation hole WLH, and the upper surface of the hard mask pattern HM. The dummy gate spacer 185P may be formed to have a uniform thickness on the bottom surface and sidewall of the plurality of contact holes CT. The dummy gate spacer 185P may fill the separation hole WLH.

In an embodiment of the present inventive concept, the dummy gate spacer 185P may include various insulation materials. For example, the dummy gate spacer 185P may include at least one of aluminum nitride (AlN), aluminum oxide (AlO), silicon oxide (SiO2), silicon oxynitride (SiON), silicon oxycarbide (SiOC), silicon oxycarbonitride (SiOCN), and/or silicon carbonitride (SiCN). In addition, the dummy gate spacer 185P may include a high dielectric constant (High-K) material.

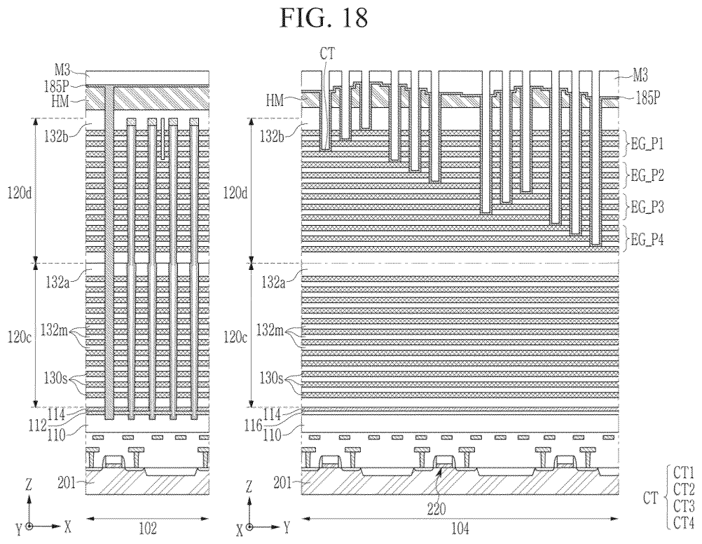

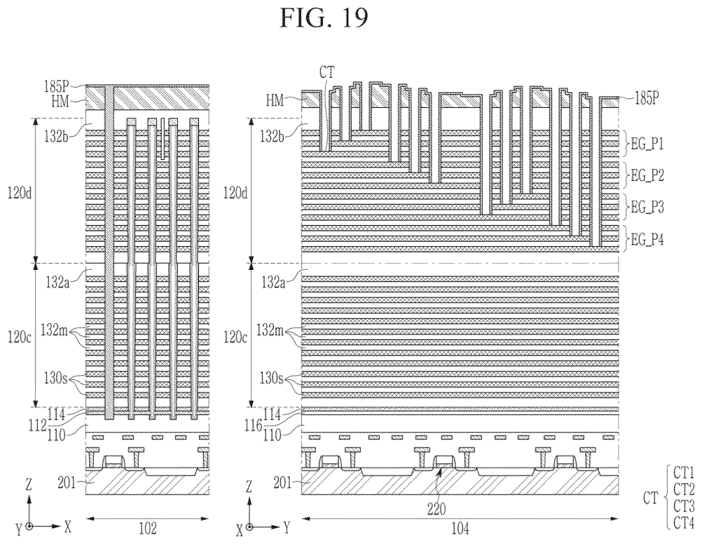

Referring to FIG. 18 and FIG. 19, a third mask pattern M3 may be formed on the dummy gate spacer 185P, and at least a part of the dummy gate spacer 185P may be removed. First, referring to FIG. 18, a third mask pattern M3 may be formed on the dummy gate spacer 185P that is positioned on the upper surface of the hard mask pattern HM. The third mask pattern M3 may expose a plurality of contact holes CT. In addition, the third mask pattern M3 may be formed in the cell array region 102, but the present inventive concept is not limited thereto. For example, the third mask pattern M3 might not be formed in the cell array region 102. In this case, the dummy gate spacer 185P that is positioned on the hard mask pattern HM may be exposed in the cell array region 102.

Next, referring to FIG. 19, the dummy gate spacer 185P exposed by the third mask pattern M3 may be removed. For example, the dummy gate spacer 185P portion positioned on the bottom surface of contact holes CT that are exposed by the third mask pattern M3 may be removed. The process of removing at least a part of the dummy gate spacer 185P may be performed by using dry etching, but the present inventive concept is not limited thereto. Accordingly, the upper surface of the sacrificial insulation layer 130s defining the bottom surface of a plurality of contact holes CT may be exposed.

Although FIGS. 18 and 19 describe that the third mask pattern M3 is formed on the dummy gate spacer 185P and at least a part of the dummy gate spacer 185P is removed, the present inventive concept is not limited thereto. For example, as illustrated in FIG. 20, at least a part of the dummy gate spacer 185P may be removed without forming a third mask pattern M3. For example, a part of the dummy gate spacer 185P which is positioned on the bottom surface of a plurality of contact holes CT, and a part of the dummy gate spacer 185P which is positioned on the hard mask pattern HM in the cell array region 102 and the contact region 104 may be removed. Accordingly, the sacrificial insulation layer 130s defining the lower surface of a plurality of contact holes CT may be exposed. In addition, the upper surface of the hard mask pattern HM may be exposed in the cell array region 102 and the contact region 104. At this time, the process of removing at least a part of the dummy gate spacer 185P may be performed by using dry etching but the present inventive concept is not limited thereto.

Referring to FIG. 21, the sacrificial contact part 184s may be formed in a plurality of contact holes CT. For example, a sacrificial contact part 184s may be formed between the dummy gate spacers 185P that are positioned within a plurality of contact holes CT. The sacrificial contact part 184s may be positioned on the exposed sacrificial insulation layer 130s in a plurality of contact holes CT. The sacrificial contact part 184s may be contact with the sacrificial insulation layer 130s. The sacrificial contact part 184s may be formed to have a sufficient thickness to fill a plurality of contact holes CT. Accordingly, a sacrificial contact part material layer may be formed on the hard mask pattern HM.

In an embodiment of the present inventive concept, the sacrificial contact part 184s may include the same material as the material of the sacrificial insulation layer 130s. For example, the sacrificial contact part 184s may include a material having etching selectivity with respect to the interlayer insulation layer 132m. For example, the sacrificial contact part 184s may include at least one of silicon, silicon oxide, silicon carbide, and/or silicon nitride.

In embodiments of the present inventive concept, after removing at least a part of the sacrificial contact part 184s, a sub-hard mask pattern SHM may be formed on the hard mask pattern HM and in the space formed by the removal of the part of the sacrificial contact part 184s. As illustrated in FIG. 22, a sub hard mask pattern SHM may be formed on the hard mask pattern HM. In the process of forming the sub-hard mask pattern SHM, at least a part of the sacrificial contact part 184s that is positioned above the plurality of contact holes CT may be removed, and a hard mask pattern material layer may be formed in the space that resulted from the removal of the part of the sacrificial contact part 184s. In addition, the sub-hard mask pattern SHM may be formed in a portion of each of the plurality of contact holes CT. In this case, the sub hard mask pattern SHM may be formed on the hard mask pattern HM. The sub hard mask pattern SHM may include the same material as that of the hard mask pattern HM.

In embodiments of the present inventive concept, if a chemical mechanical polishing process is performed after forming a sub-hard mask pattern SHM, the hard mask pattern HM may be smoothly removed.

Referring to FIGS. 23 and 24, the gate spacer 185 and the separation structure 146 may be simultaneously formed by removing the hard mask pattern HM by using a chemical mechanical polishing process.

In an embodiment of the present inventive concept, the sub hard mask pattern SHM positioned on the hard mask pattern HM may be removed by using a chemical mechanical polishing process.

At this time, by forming a sacrificial contact part 184s in a plurality of contact holes CT, by-product material might not be formed in a plurality of contact holes CT while removing the hard mask pattern HM.

At this time, the hard mask pattern HM and a portion of the dummy gate spacer 185P overlapping the hard mask pattern HM in the first direction (X direction) and the second direction (Y direction) may be removed together. Accordingly, the gate spacer 185 and the separation structure 146 may be formed. In addition, the upper surface of the sacrificial contact part 184s and the upper surface of the upper insulation layer 132b may be exposed.

In addition, at least a part of the upper insulation layer 132b may be removed together with the hard mask pattern HM. For example, at least a part of the upper insulation layer 132b may include recess parts RCS1 and RCS2 that are concave protruding toward the upper surface of the second substrate 110.

Referring further to FIG. 24, the upper insulation layer 132b may include a first recess part RCS1 positioned in the contact region 104 and a second recess part RCS2 positioned in the cell array region 102.

The first recess part RCS1 may be positioned between a plurality of gate contact parts 184. For example, the first recess part RCS1 may be positioned between a plurality of gate contact part 184 which is positioned spaced apart in the second direction (Y direction). The first recess part RCS1 may have a concave shape protruding toward the upper surface of the second substrate 110. For example, the first recess part RCS1 may have a concave shape protruding toward the upper surface of the second substrate 110 between neighboring gate contact parts 184 of the plurality of gate contact parts 184. The first recess part RCS1 may include a curved surface having a predetermined curvature in a cross sectional view, but the present inventive concept is not limited thereto.

The second recess part RCS2 may be positioned between the separation structures 146.

For example, the second recess part RCS2 may be positioned between the separation structures 146 positioned apart in the first direction (X direction). The second recess part RCS2 may be positioned on the channel structure CH. The second recess part RCS2 may have a concave shape protruding toward the upper surface of the second substrate 110. For example, the second recess part RCS2 may have a concave shape protruding toward the upper surface of the second substrate 110 between the separation structures 146. The second recess part RCS2 may include a curved surface having a predetermined curvature in a cross sectional view, but the present inventive concept is not limited thereto. For example, the curvature of the second recess part RCS2 may be less than the curvature of the first recess part RCS1.

In an embodiment of the present inventive concept, a degree in which at least a part of the upper insulation layer 132b positioned in the cell array region 102 is removed may be greater than a degree in which at least a part of the upper insulation layer 132b positioned in the contact region 104 is removed. This is because the distance of between the separation structures 146 adjacent to each other in the first direction (X direction) is greater than the distance of between the gate spacers 185 adjacent to each other in the second direction (Y direction) in the process of removing the hard mask pattern HM that is positioned on the upper insulation layer 132b by using a chemical mechanical polishing process. In other words, the width of the first recess part RCS1 that is formed between the gate spacers 185 that are adjacent to each other in the second direction (Y direction) may be narrower than the width of the second recess part RCS2 provided between the separation structures 146 that are adjacent to each other in the first direction (X direction).

Accordingly, a recessed depth of the second recess part RCS2 may be greater than a recessed depth of the first recess part RCS1. For example, the minimum length from the upper surface of the gate electrode 130 positioned at the uppermost part of the gate electrodes 130 to the upper surface of the second recess part RCS2 may be shorter than the minimum length from the upper surface of the gate electrode 130 positioned at the uppermost part of the gate electrodes 130 to the upper surface of the first recess part RCS1. In addition, in the cross section made up of the first direction (X direction) and the third direction (Z direction), the curvature of the second recess part RCS2 may be less than the curvature of the first recess part RCS1 in the cross section made up of the second direction (Y direction) and the third direction (Z direction). In the method of manufacturing the semiconductor device 10 according to an embodiment of the present inventive concept, while removing the hard mask pattern HM positioned on the upper insulation layer 132b, at least a part of the upper insulation layer 132b may be removed with the hard mask pattern HM. In this case, a gate spacer 185 and a sacrificial contact part 184s are formed in a plurality of contact holes CT penetrating the upper insulation layer 132b before removing the hard mask pattern HM, and then a separation structure 146 may be formed. When removing the hard mask pattern HM by using a chemical mechanical polishing process, the gate spacer 185 and the separation structure 146 might not be removed. Therefore, the degree to which a part of the upper insulation layer 132b that is adjacent to the gate spacer 185 is removed from the contact region 104 may be relatively reduced, and the sacrificial contact part 184s may be prevented from being removed. In addition, the degree to which a part of the upper insulation layer 132b that is adjacent to the separation structure 146 is removed from the cell array region 102 may be relatively reduced, thereby preventing the channel structure CH from being exposed. Accordingly, the reliability of the semiconductor device 10 may be increased.

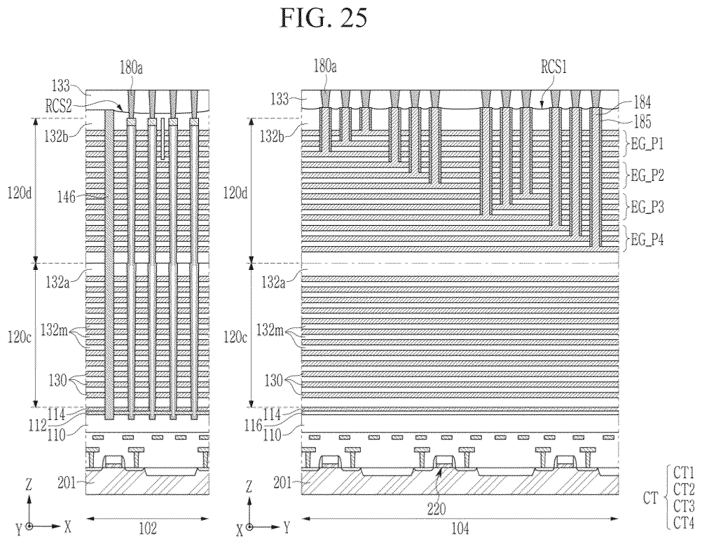

Referring to FIG. 25, a plurality of gate electrodes 130 and a plurality of gate contact parts 184 may be formed simultaneously by removing the sacrificial contact part 184s and the sacrificial insulation layer 130s.

First, the sacrificial contact part 184s and the sacrificial insulation layer 130s may be removed. The sacrificial contact part 184s and the sacrificial insulation layer 130s may be selectively removed by using an etching solution with etching selectivity for the interlayer insulation layer 132m.

Subsequently, a plurality of gate electrodes 130 and a plurality of gate contact parts 184 may be formed in the removed space. A plurality of gate electrodes 130 and a plurality of gate contact parts 184 may be formed by depositing conductive materials such as tungsten (W), copper (Cu), and aluminum (Al) in a space where the sacrificial contact part 184s and the sacrificial insulation layer 130s were removed from.

For example, the width of plurality of contact holes CT along the second direction (Y direction) may be the minimum width of plurality of contact holes CT along the second direction (Y direction).

Therefore, in an embodiment of the present inventive concept, a plurality of gate electrodes 130 may be formed before a plurality of gate contact parts 184 are completely formed. Accordingly, it is possible to prevent the occurrence of voids in the plurality of gate electrodes 130 and increase the reliability of the semiconductor device 10.

Next, a contact insulation layer 133 may be formed on the upper insulation layer 132b, and a contact via 180a may be formed through the contact insulation layer 133 and may be connected to the channel structure CH and the plurality of gate contact parts 184, respectively. Furthermore, a semiconductor device 10 according to an embodiment of the present inventive concept may be formed through forming a bit line (182 of FIG. 1) and a connection wire (190 of FIG. 1) connected to the contact via 180a.

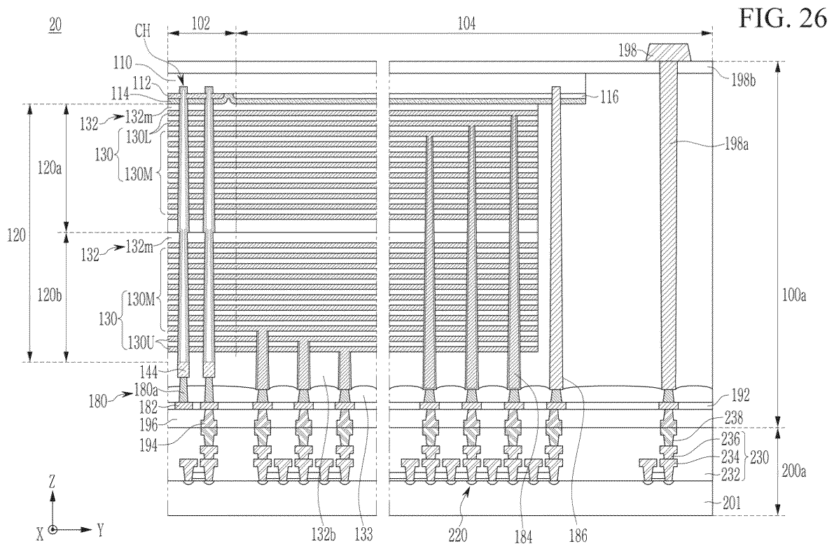

Next, referring to FIG. 26, a semiconductor device according to embodiments of the present inventive concept will be described.

FIG. 26 is a cross-sectional view of a semiconductor device according to embodiments of the present inventive concept. Since the embodiment shown in FIG. 26 has many of the same parts as the embodiment shown in FIG. 1 to FIG. 7, a description thereof will be omitted and differences therebetween will be mainly described. Redundant descriptions may be omitted or briefly discussed. In addition, the same reference numerals are used for the same components.

Referring to FIG. 26, a semiconductor device 20 according to an embodiment of the present inventive concept may have a chip to chip (C2C) structure joined by a wafer bonding method. That is, a lower chip including a circuit region 200a formed on the first substrate 201 may be manufactured, an upper chip including a cell region 100a formed on the second substrate 110 may be manufactured, and then the semiconductor device 20 may be manufactured by bonding the chips. The circuit region 200a may have a first junction structure 238 on a surface thereof that faces the cell region 100a on the first substrate 201, the circuit element 220, and a first wire part 230.

The cell region 100a may have a second junction structure 194 disposed on the circuit region 200a, the gate stacking structure 120, the channel structure CH, and the second wire part 180.

In the gate stacking structure 120, a plurality of gate electrodes 130 may include a lower gate electrode 130L, a memory cell gate electrode 130M, and an upper gate electrode 130U sequentially positioned from the second substrate 110 toward the circuit region 200a. For example, as illustrated in FIG. 26, the gate stacking structure 120 may be sequentially stacked under the second substrate 110 in the drawing, and the gate stacking structures 120 illustrated in FIGS. 1 to 7 may have a vertically inverted and arranged shape in FIG. 26.

Accordingly, the channel pad 144 and the second wire part 180 positioned on the gate stacking structure 120 may be positioned adjacent to the circuit region 200a. In addition, a second junction structure 194 electrically connected to the second wire part 180 may be provided on a surface facing the circuit region 200a. An insulation layer 196 may be disposed on the circuit region 200a and may at least partially surround the second junction structure 194. In this way, the second wire part 180 and the second junction structure 194 may be positioned to face the circuit region 200a in the cell region 100a.

For example, the second junction structure 194 of the cell region 100a and the first junction structure 238 of the circuit region 200a may be made of aluminum, copper, tungsten, or an alloy thereof. For example, as the first and second junction structure 238 and 194 include copper, the cell region 100a and the circuit region 200a may be connected (for example, directly contacted and bonded) to each other by copper-to-copper bonding.

FIG. 26 illustrates that the gate stacking structure 120 includes a plurality of gate structures 120a and 120b, and the gate stacking structure 120 may be formed of a single gate stacking structure. Except where otherwise is described, the description of the structures of the gate stacking structure 120 and the channel structure CH described with reference to FIG. 1 to FIG. 7 may be applied as it is to FIG. 26. In FIG. 26, the electrical connection structure between the channel structure CH and the horizontal conductive layers 112 and 114 and/or the second substrate 110 is illustrated to be the same as FIG. 1. The embodiment is not limited thereto, and the electrical connection structure between the channel structure CH, the horizontal conductive layers 112 and 114 and/or the second substrate 110 may be variously changed.

The semiconductor device 20 according to an embodiment of the present inventive concept may include an input/output pad 198 and an input/output connection wire 198a electrically connected thereto. The input/output connection wire 198a may be electrically connected to a part of the second junction structure 194. The input/output pad 198 may be positioned, for example, on the insulation layer 198b covering the outer surface of the second substrate 110. For example, the input/output connection wire 198a may penetrate the upper insulation layer 132 to connect the input/output pad 198 to the second junction structure 194. According to an embodiment of the present inventive concept, a separate input/output pad electrically connected to the circuit region 200a may be provided.

For example, the circuit region 200a and the cell region 100a may be portions corresponding to the first structure 1100F and the second structure 1100S of the semiconductor device 1100 included in the electronic system 1000 shown in FIG. 27, respectively. In addition, the circuit region 200a and the cell region 100a may be parts corresponding to the first structure 4100 and the second structure 4200 of the semiconductor chip 2200 shown in FIG. 30, respectively. Next, referring to FIG. 27, an electronic system including a semiconductor device according to an embodiment of the present inventive concept will be described.

FIG. 27 is a schematic view of an electronic system including a semiconductor device according to an embodiment of the present inventive concept.

As shown in FIG. 27, an electronic system 1000 according to an embodiment of the present inventive concept may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid-state drive device SSD that includes one or more semiconductor devices 1100, a universal serial bus (USB), a computing system, a medical device, or a communication device.

The semiconductor device 1100 may be a nonvolatile memory device, for example, a NAND flash memory device described with reference to FIG. 1 to FIG. 25. The semiconductor device 1100 may include a first structure 1100F and a second structure 1100S on the first structure 1100F. In an embodiment of the present inventive concept, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, the first and second gate upper lines UL1 and UL2, the first and second gate lower lines LL1 and LL2, and a memory cell string CSTR between the bit line BL and the common source line CSL.

In the second structure 1100S, each of the memory cell strings CSTR may include lower transistors LT1 and LT2 adjacent to the common source line CSL, upper transistors UT1, UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed according to an embodiment of the present inventive concept.

In an embodiment of the present inventive concept, the lower transistors LT1 and LT2 may include a ground selection transistor, and the upper transistors UT1 and UT2 may include a string selection transistor. Each of the first and second gate lower lines LL1 and LL2 may be a gate electrode of the lower transistors LT1 and LT2, respectively. The word line WL may be a gate electrode of the memory cell transistor MCT, and the first and second gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through first connection wires 1115 extending from the first structure 1100F to the second structure 1100S. The bit line BL may be electrically connected to the page buffer 1120 through a second connection wire 1125 extending from the first structure 1100F to the second structure 1100S.

In the first structure 1100F, the decoder circuit 1110 and the page buffer 1120 may perform a control operation on at least one memory cell transistor selected from a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending from the first structure 1100F to the second structure 1100S.

The controller 1200 may include a processor 1210, a NAND controller 1220, and a host interface 1230. According to an embodiment of the present inventive concept, the electronic system 1000 may include a plurality of semiconductor devices 1100, and in this case, the controller 1200 may control a plurality of semiconductor devices 1100.

The processor 1210 may control the overall operation of the electronic system 1000 including the controller 1200. A processor 1210 may operate according to predetermined firmware and may access the semiconductor device 1100 by controlling the NAND controller 1220. The NAND controller 1220 may include a NAND interface 1221 for processing communication with the semiconductor device 1100. A control instruction for controlling the semiconductor device 1100, data for recording in the memory cell transistor MCT of the semiconductor device 1100, data to be read from the memory cell transistor MCT of the semiconductor device 1100 and the like may be transmitted through the NAND interface 1221. A host interface 1230 may provide a communication function between the electronic system 1000 and an external host. Upon receiving a control instruction from an external host through the host interface 1230, the processor 1210 may control the semiconductor device 1100 in response to the control instruction.

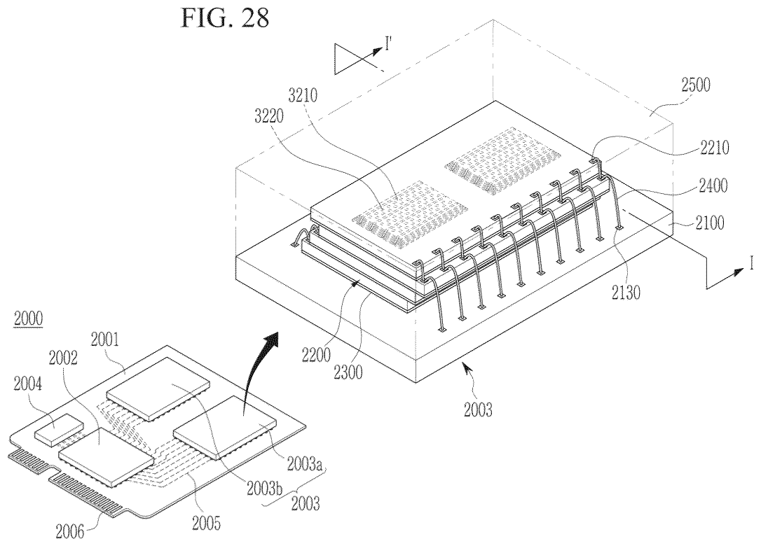

FIG. 28 is a perspective view of an electronic system including a semiconductor device according to an embodiment of the present inventive concept.

As shown in FIG. 28, an electronic system 2000 according to an embodiment of the present inventive concept may include a main substrate 2001, a controller 2002 mounted on the main substrate 2001, one or more semiconductor packages 2003, and a DRAM 2004. The semiconductor package 2003 and the DRAM 2004 may be connected to the controller 2002 by a wire pattern 2005 that is formed on the main substrate 2001.

The main substrate 2001 may include a connector 2006 including a plurality of pins coupled to an external host. The number and arrangement of the plurality of pins in the connector 2006 may vary depending on the communication interface between the electronic system 2000 and the external host. In an embodiment of the present inventive concept, the electronic system 2000 may communicate with an external host according to any one of interfaces such as universal serial bus (USB), peripheral component interconnect express (PCI-Express), serial advanced technology attachment (SATA), and M-Phy for universal flash storage (UFS). In an embodiment of the present inventive concept, the electronic system 2000 may operate by power supplied from an external host through the connector 2006. The electronic system 2000 may further include a power management integrated circuit (PMIC) for distributing power supplied from the external host to the controller 2002 and the semiconductor package 2003.

The controller 2002 may record data in the semiconductor package 2003, read data from the semiconductor package 2003, and increase the operation speed of the electronic system 2000.

The DRAM 2004 may be a buffer memory for mitigating a speed difference between the semiconductor package 2003, which is a data storage space, and the external host. As a kind of cache memory, the DRAM 2004 included in the electronic system 2000 may be operated and may also provide a space for temporarily storing data in the control operation of the semiconductor package 2003. When DRAM 2004 is included in the electronic system 2000, the controller 2002 may further include a DRAM controller for controlling DRAM 2004 in addition to a NAND controller for controlling the semiconductor package 2003. The semiconductor package 2003 may include a first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a semiconductor chip 2200 on the package substrate 2100, an adhesive layer 2300 disposed on a bottom surface of each of the semiconductor chips 2200, a connection structure 2400 electrically connecting the semiconductor chip 2200 with the package substrate 2100, and a molding layer 2500 covering the semiconductor chip 2200 and the connection structure 2400 on the package substrate 2100.

The package substrate 2100 may be a printed circuit board including the package upper pad 2130. Each semiconductor chip 2200 may include an input/output pad 2210. The input/output pad 2210 may correspond to the input/output pad 1101 of FIG. 27. Each semiconductor chips 2200 may include a gate stacking structure 3210 and a channel structure 3220. Each of the semiconductor chips 2200 may include the semiconductor device described with reference to FIG. 1 to FIG. 25. Each of the semiconductor chips 2200 may include the semiconductor device described with reference to FIG. 1 to FIG. 25. Therefore, in each of the first and second semiconductor packages 2003a and 2003b, the semiconductor chips 2200 may be electrically connected to each other in a bonding wire method, and may be electrically connected to the package upper pad 2130 of the package substrate 2100.

According to an embodiment of the present inventive concept, in each of the first and second semiconductor packages 2003a and 2003b, the semiconductor chips 2200 may be electrically connected to each other by a connection structure including a passing electrode (e.g., a Through Silicon Via TSV) instead of connection structure 2400 of a wire bonding type. In an embodiment of the present inventive concept, the controller 2002 and the semiconductor chip 2200 may be included in one package. For example, a controller 2002 and a semiconductor chip 2200 may be mounted on a separate interposer substrate different from the main substrate 2001, and the controller 2002 and the semiconductor chip 2200 may be connected to each other by wire formed on the interposer substrate.

FIG. 29 and FIG. 30 are cross-sectional views of a semiconductor package according to an embodiment of the present inventive concept. FIGS. 29 and 30 describe the semiconductor package 2003 of FIG. 28 according to an embodiment of the present inventive concept, and conceptually illustrate a region in which the semiconductor package 2003 of FIG. 28 is cut along the cutting line I-I′, respectively.

Referring to FIG. 29, in the semiconductor package 2003, the package substrate 2100 may be a printed circuit board. The package substrate 2100 may include a package substrate body part 2120, a package upper pad 2130 disposed on the upper surface of the package substrate body part 2120, a lower pad 2125 disposed on the lower surface of the package substrate body part 2120 or exposed through the lower surface, and an internal wire 2135 electrically connecting the upper pad 2130 and the lower pad 2125 to each other in the package substrate body part 2120. The upper pad 2130 may be electrically connected to the connection structure 2400. The lower pad 2125 may be connected to the wire pattern 2005 of the main substrate 2001 of the electronic system 2000 as shown in FIG. 28 through the conductive connection part 2800.

Each semiconductor chip 2200 may include a first structure 3100 and a second structure 3200 sequentially stacked on a semiconductor substrate 3010. The first structure 3100 may include a peripheral circuit region including the peripheral wire 3110. The second structure 3200 may include a common source line 3205, a gate stacking structure 3210 on the common source line 3205, a channel structure 3220 and a separation structure 3230 penetrating the gate stacking structure 3210, a bit line 3240 electrically connected to the channel structure 3220, and a gate connection wire electrically connected to a word line WL of FIG. 27 of the gate stacking structure 3210.

In an embodiment of semiconductor chip 2200 or semiconductor device, as the first width W1 according to the second direction (Y direction) of the plurality of gate contact parts 184 is greater than or equal to the thickness according to the third direction (Z direction) of a plurality of gate electrodes 130, the plurality of gate electrodes 130 may be formed before the plurality of gate contact parts 184 is formed completely. Accordingly, it is possible to prevent the formation of voids within the plurality of gate electrodes 130 and increase the reliability of the semiconductor device 10.

In addition, in the semiconductor chip 2200 or the semiconductor device according to an embodiment of the present inventive concept, the gate spacer 185 and the separation structure 146 might not be removed when the hard mask pattern HM is removed by using a chemical mechanical polishing process. Therefore, in contact region 104, the degree in which a part of the upper insulation layer 132b that is adjacent to the gate spacer 185 is removed may be relatively reduced, thereby preventing the sacrificial contact part 184s being removed. In addition, in the cell array region 102, the degree in which a part of the upper insulation layer 132b that is adjacent to the separation structure 146 is removed may be relatively reduced, thereby preventing the channel structure CH from being exposed. Accordingly, the reliability of the semiconductor device 10 may be increased.

Each semiconductor chip 2200 may be connected to the peripheral wire 3110 of the first structure 3100 and may include a passing wire 3245 electrically connected to and extending to the second structure 3200 from the first structure 3100. The passing wire 3245 may penetrate the gate stacking structure 3210 and may be further arranged on the outside of the gate stacking structure 3210. Each semiconductor chip 2200 may further include an input/output connection wire 3265 electrically connected to the peripheral wire 3110 of the first structure 3100 and extending into the second structure 3200, and an input/output pad 2210 electrically connected to the input/output connection wire 3265.

In an embodiment of the present inventive concept, the plurality of semiconductor chips 2200 may be electrically connected to each other by the bonding wire shaped connection structure 2400 in the semiconductor package 2003. In another example, a plurality of semiconductor chips 2200 or a plurality of parts constituting the chips may be electrically connected by a connection structure including a passing electrode (e.g., a Through Silicon Via, TSV).

Referring to FIG. 30, in the semiconductor package 2003a, each semiconductor chip 2200 may include the semiconductor substrate 4010, the first structure 4100 on the semiconductor substrate 4010, and the second structure 4200 connected with the first structure 4100 with a wafer bonding method. The second structure 4200 may be disposed on the first structure 4100.

The first structure 4100 may include a peripheral circuit region comprising a peripheral wire 4110 and a first junction structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second junction structure 4250 electrically connected respectively to the channel structure 4220 and the word line (hereinafter, WL of FIG. 27) of the gate stacking structure 4210. For example, the second junction structure 4250 may be electrically connected to the channel structure 4220 and the word line WL, respectively, through a bit line 4240 electrically connected to the channel structure 4220 and a gate connection wire electrically connected to the word line WL.

The first junction structure 4150 of the first structure 4100 and the second junction structure 4250 of the second structure 4200 may be bonded to each other while contacting each other. The joint part of the first junction structure 4150 and the second junction structure 4250 may be formed of copper (Cu), for example.

In the semiconductor chip 2200 or the semiconductor device according to an embodiment of the present inventive concept, since the first width W1 in the second direction (Y direction) of the plurality of gate contact parts 184 is greater than or equal to the thickness in the third direction (Z direction) of the plurality of gate electrodes 130, a plurality of gate electrodes 130 may be formed before the plurality of gate contact parts 184 are completely formed. Accordingly, it is possible to prevent the formation of voids in the plurality of gate electrodes 130 and increase the reliability of the semiconductor device 10.

In addition, in the semiconductor chip 2200 or the semiconductor device according to an embodiment of the present inventive concept, the gate spacer 185 and the separation structure 146 might not be removed when the hard mask pattern HM is removed by using a chemical mechanical polishing process. Therefore, the degree to which a part of the upper insulation layer 132b that is adjacent to gate spacer 185 is removed from the contact region 104 may be relatively reduced, and the sacrificial contact part 184s may be prevented from being removed. In addition, the degree to which a part of the upper insulation layer 132b that is adjacent to the separation structure 146 is removed from the cell array region 102 may be relatively reduced, thereby preventing the channel structure CH from being exposed. Accordingly, the reliability of the semiconductor device 10 may be increased.

Each of the semiconductor chips 2200 may further include an input/output pad 2210 and an input/output connection wire 4265 under the input/output pad 2210. The input/output connection wire 4265 may be electrically connected to a part of the second junction structure 4250.

In an embodiment of the semiconductor package 2003a, a plurality of semiconductor chips 2200 may be electrically connected to each other by the bonding wire shaped connection structure 2400. In an embodiment of the present inventive concept, a plurality of semiconductor chips 2200 or a plurality of parts constituting the chips may be electrically connected to each other by a connection structure comprising a passing electrode.

While the present inventive concept has been shown and described with reference to the embodiments thereof, it will be apparent to those of ordinary skill in the art that various changes in form and detail may be made thereto without departing from the spirit and scope of the present inventive concept.

### DESCRIPTION OF SYMBOLS

100: cell region
200: circuit region
110: second substrate
102: cell array region
104: contact region
120: gate stacking structure
CH: channel structure
130: plurality of gate electrode
184: plurality of gate contact part
185: gate spacer
132b: upper insulation layer

What is claimed is:

1. A semiconductor device comprising:
a substrate comprising a cell array region and a contact region;
a gate stacking structure including a plurality of interlayer insulation layers and a plurality of gate electrodes which are alternately stacked on the substrate;
a channel structure penetrating the gate stacking structure in the cell array region;
an upper insulation layer covering the gate stacking structure and the channel structure; and
a plurality of gate contact parts penetrating the upper insulation layer and connected to the plurality of gate electrodes in the contact region,
wherein at least a part of some of the plurality of gate contact parts penetrates at least one passing gate electrode among the plurality of gate electrodes and integrates with a connection gate electrode, of the plurality of gate electrodes, positioned under the at least on passing gate electrode, and
at least a part of an upper surface of the upper insulation layer has a concave shape protruding toward the substrate.

2. The semiconductor device of claim 1, further comprising:
a separation structure penetrating the gate stacking structure in the cell array region,
wherein a maximum width of the separation structure is narrower than a maximum width of each of the plurality of gate contact parts.

3. The semiconductor device of claim 2, wherein:
an upper surface of the separation structure and the upper surface of each of the plurality of gate contact parts are positioned at substantially the same distance from an upper surface of the substrate.

4. The semiconductor device of claim 2, further comprising:
a gate spacer at least partially surrounding each of the plurality of gate contact parts,
wherein the separation structure has a same material as that of the gate spacer.

5. The semiconductor device of claim 1, further comprising:
a gate spacer at least partially surrounding each of the plurality of gate contact parts,
wherein a bottom surface of the gate spacer contacts is disposed on the connection gate electrode.

6. The semiconductor device of claim 5, wherein:
the gate spacer comprises at least one of AlN, AIO, SiOC, SiOCN, SiCN, or High-K materials.

7. The semiconductor device of claim 5, wherein:
a thickness of the gate spacer is about 1/12^{th} to about ⅛^{th} of the thickness of each of the plurality of gate contact parts.

8. The semiconductor device of claim 1, wherein:
the upper insulation layer comprises:
a first recess part having a concave shape protruding toward the substrate in the contact region,
wherein an upper surface in the center of the first recess part is positioned closer to an upper surface of the substrate than an upper surface of each of the plurality of gate contact parts.

9. The semiconductor device of claim 8, wherein:
the upper insulation layer further comprises:
a second recess part having a concave shape protruding toward the substrate in the cell array region, and
wherein a bottom surface of the first recess part is positioned farther from the upper surface of the substrate than a bottom surface of the second recess part.

10. The semiconductor device of claim 9, wherein:
a curvature of the second recess part is less than a curvature of the first recess part.

11. The semiconductor device of claim 1, wherein:
the plurality of gate contact parts includes a same material as that of the plurality of gate electrodes, and
a thickness of each of the plurality of gate contact parts is greater than or equal to a thickness of the plurality of gate electrodes in the one direction.

12. The semiconductor device of claim 1, wherein:
side surfaces of the plurality of interlayer insulation layers and side surfaces of the plurality of gate electrodes are substantially coplanar.

13. An electronic system comprising:
a main substrate;
a semiconductor device on the main substrate; and
a controller electrically connected to the semiconductor device on the main substrate,
wherein the semiconductor device comprises:
a circuit region including a peripheral circuit structure;
a cell region positioned on the circuit region;
a substrate including a cell array region and a contact region adjacent to the cell region;
a gate stacking structure including a plurality of interlayer insulation layers and a plurality of gate electrodes which are alternately stacked on the substrate;
a channel structure penetrating the gate stacking structure and extending in one direction in the cell array region;
an upper insulation layer covering the gate stacking structure and the channel structure; and
a plurality of gate contact parts penetrating the upper insulation layer and connected to the plurality of gate electrodes in the contact region,
wherein, at least a part of some of the plurality of gate contact parts penetrates at least one passing gate electrode among the plurality of gate electrodes and is connected to a connection gate electrode, of the plurality of gate electrodes, positioned under the at least one passing gate electrode, and
at least a part of an upper surface of the upper insulation layer has a concave shape protruding toward the substrate.

14. The electronic system of claim 13, further comprising:
a separation structure penetrating the gate stacking structure in the cell array region,
wherein a maximum thickness of the separation structure is less than a maximum thickness of each of the plurality of gate contact parts.

15. The electronic system of claim 13, further comprising:
a gate spacer at least partially surrounding each of the plurality of gate contact parts,
wherein a bottom surface of the gate spacer contacts the connection gate electrode.

16. The electronic system of claim 13,
wherein the upper insulation layer comprises:
a first recess part having a concave shape protruding toward the substrate in the contact region; and
a second recess part having a concave shape protruding toward the substrate in the cell array region,
wherein an upper surface of the first recess part is positioned farther from an upper surface of the substrate than an upper surface of the second recess part.

17. A method for manufacturing a semiconductor device, the method comprising:
forming a stacking structure by alternately stacking a sacrificial insulation layer and an interlayer insulation layer on a substrate, which includes a first region and a second region;
forming an upper insulation layer on the stacking structure;
forming a channel structure penetrating the stacking structure in the first region;
forming a plurality of contact holes penetrating at least a part of the stacking structure by using a mask pattern and having different depths from each other in the second region;
forming a gate spacer on sidewalls of the plurality of contact holes;
forming a sacrificial contact part in the plurality of contact holes;
removing the mask pattern by using a chemical mechanical polishing process; and
removing the sacrificial insulation layer and the sacrificial contact part; and
forming a plurality of gate electrodes and a plurality of gate contact parts in spaces that are formed by the removal of the sacrificial insulation layer and the sacrificial contact part,
wherein, when the mask pattern is removed, at least a part of the upper insulation layer is removed with the mask pattern.

18. The method of claim 17, wherein:
when the plurality of contact holes is formed, the stacking structure and a separation hole that penetrates at least a part of the substrate are formed together in the first region,
when the gate spacer is formed, a separation structure filling the separation hole is formed in the first region, and
wherein the separation structure has a same material as that of the gate spacer.

19. The method of claim 17, wherein:
wherein the forming the gate spacer comprises:
forming a dummy gate spacer on an upper surface of the upper insulation layer, and a bottom surface and a sidewall of the plurality of contact holes; and
removing the dummy gate spacer positioned on the bottom surface of the plurality of contact holes and exposing the sacrificial insulation layer.

20. The method of claim 17, wherein:
at least a part of the upper surface of the upper insulation layer comprises a concave shape protruding toward the substrate.
